(19) United States
(12) Patent Application Publication
(10) Pub. No.: US 2016/0172531 A1
(43) Pub. Date: Jun. 16, 2016

(54) TRANSPARENT ELECTROCONDUCTIVE FILM FOR SOLAR CELL, COMPOSITION FOR TRANSPARENT ELECTROCONDUCTIVE FILM AND MULTI-JUNCTION SOLAR CELL

(71) Applicant: MITSUBISHI MATERIALS CORPORATION, Tokyo (JP)

(72) Inventors: Masahide Arai, Akita-shi (JP); Kazuhiko Yamasaki, Naka-shi (JP); Satoko Ogawa, Naka-gun (JP); Toshiharu Hayashi, Toyko (JP)

(21) Appl. No.: 15/050,020

(22) Filed: Feb. 22, 2016

Related U.S. Application Data
(62) Division of application No. 14/100,511, filed on Dec. 9, 2013.
Application No. 14/100,511 is a division of application No. 12/737,679, filed on Feb. 4, 2011, now abandoned.

(30) Foreign Application Priority Data
Aug. 27, 2008 (JP) 2008-218338
Aug. 27, 2008 (JP) 2008-218342
Jul. 24, 2009 (JP) 2009-173397
Jul. 24, 2009 (JP) 2009-173403

(51) Int. Cl. H01L 31/18; H01L 31/0376; H01L 31/0687

(52) U.S. Cl. CPC H01L 31/1884; H01L 31/0687; H01L 31/03762

(57) ABSTRACT

An object of the present invention is to provide a transparent electroconductive film, which in addition to satisfying each of the requirements of favorable phototransmittance, high electrical conductivity, low refractive index and the like required when using in a multi-junction solar cell, enables running costs to be reduced since the transparent electroconductive film is produced without using a vacuum deposition method. The transparent electroconductive film for a solar cell of the present invention is provided between photoelectric conversion layers of a multi-junction solar cell, a coated film of fine particles formed by coating using a wet coating method is baked, the electroconductive component in the base material that composes the electroconductive film is present within the range of 5 to 95% by weight, and the thickness of the electroconductive film is within the range of 5 to 200 nm.

### TECHNICAL FIELD

The present invention relates to a transparent electroconductive film for a solar cell that improves cell output by being provided between photoelectric conversion layers in a multi-junction solar cell having improved conversion efficiency by laminating two or more types of photoelectric conversion layers, a composition for that transparent electroconductive film, and a multi-junction solar cell.

### BACKGROUND ART

Research and development of clean energy are currently proceeding from the standpoint of environmental protection. In particular, solar cells are attracting attention since they use infinitely available sunlight for their energy source and are non-polluting. In the past, bulk solar cells were used for solar power generation by solar cells, and these were used as semiconductors in the form of thick plates obtained by producing bulk crystals of monocrystalline silicon or polycrystalline silicon and then slicing the crystals into thick plates. However, the silicon crystals used in bulk solar cells required considerable time and energy to grow the crystals and a complicated process was required in the subsequent production process, thereby making it difficult to increase volume production efficiency and making it difficult to provide inexpensive solar cells.

On the other hand, thin film semiconductor solar cells (to be referred to as thin film solar cells) using semiconductors such as amorphous silicon having a thickness of several micrometers or less only required the formation of a required number of semiconductor layers serving as photoelectric conversion layers on an inexpensive substrate such as glass or stainless steel. Thus, these thin film solar cells are considered to become the mainstream of future solar cells since they are thin and lightweight, have a low production cost and can easily be adapted to applications invoicing a large surface area.

In the case of thin film solar cells in which the photoelectric conversion, layers are formed from a silicon-based material, studies have been conducted on enhancing power generation efficiency by adopting a multi-junction structure in which, for example, a transparent electrode, amorphous silicon, polycrystalline silicon and a surface electrode are formed in that order (see, for example, patent Documents 1 to 4 and Non-Patent Document 1). In the structure indicated in Patent Documents 1 to 4 and Non-Patent Document 1, amorphous silicon and polycrystalline silicon compose the photoelectric conversion layers.

In the case of composing the photoelectric conversion layers with a silicon-based material, since the absorption coefficient of the photoelectric conversion layers is comparatively small, a portion of the incident light ends up passing through the photoelectric conversion layers in the case the film thickness of the photoelectric conversion layers is on the order of several micrometers, thereby presenting the light that has passed through from contributing to power generation.

Consequently, a transparent electroconductive film is provided as an intermediate film between a top cell and a bottom cell for each layer that composes a thin film solar cell (see, for example, Patent Documents 1 to 3 and Non-Patent Document 1).

The inherent purpose of this transparent electroconductive film is to wavelength-selectively reflect a portion of light that enters the bottom cell by passing through the top cell by utilizing a difference in refractive indices between a silicon layer and this transparent electroconductive film. For example, in the case of a solar cell employing a tandem structure consisting of an amorphous silicon layer (top cell) and a microcrystalline silicon layer (bottom cell), by providing a transparent electroconductive film at the interface of both photoelectric conversion layers, short wavelength light, indicating that the amorphous silicon has a high conversion efficiency, is selectively reflected by this transparent electroconductive film. Since the short wavelength reflected light reenters the amorphous silicon layer, it can again contribute to power generation. As a result, effective photosensitivity increases in comparison with a conventional structure for the same top cell film thickness. On the other hand, the majority of long wavelength light passes through this transparent electroconductive film, and enters the microcrystalline silicon layer having high conversion efficiency for long wavelength light.

### PRIOR ART DOCUMENTS

### Patent Documents

Patent Document 1: Japanese Unexamined Patent Application, First Publication No. 2006-319068

Patent Document 2: Japanese Unexamined Patent Application, First Publication No. 2006-310694

Patent Document 3: International Publication No. WO 2005/011002

Patent Document 4: Japanese Unexamined Patent Application, First Publication No. 2002-141524

### Non-Patent Documents

Non-Patent Document 1: Yanagida, S., et al.: “Development Front Line of Thin Film Solar Cells-Towards Higher Efficiency, Volume Production and Promotion of Proliferation”, NTS Co., Ltd., March 2005, p. 113, FIG. 1(a)

### SUMMARY OF THE INVENTION

### Problems to be Solved by the Invention

Previous development in the field of thin film solar cells has consisted of forming each layer by a vacuum deposition method such as sputtering. However, since large-scale vacuum deposition systems typically require considerable costs for maintenance and operation, considerable improvement in running costs are expected to be achieved by replacing production methods using a vacuum deposition process with production methods using a wet film deposition process.

In addition, it was necessary for transparent electroconductive films to at least satisfy requirements such as favorable phototransmittance, high electrical conductivity, low refractive index and sputtering resistance.

Moreover, one of the important characteristics of multi-junction solar cells is that short-circuit current density is limited by the smallest short-circuit current density among short-circuit current density generated in each photoelectric conversion layer. Short-circuit circuit density throughout an entire cell is known to be increased by optimizing the short-circuit current density generated in each photoelectric conversion layer by adjusting the light reflection properties within a cell using a transparent electroconductive film.

An object of the present invention is to provide a transparent electroconductive film for a solar cell which, in addition to being able to satisfy various requirements such as favorable phototransmittance, high electrical conductivity and low refractive index that are required when using in a multi-junction solar cell by being produced by a wet coating method using a coating material, also reduces running costs by being produced without using a vacuum deposition method.

Another object of the present invention is to provide a transparent electroconductive film for a solar cell capable of optimizing light reflection properties between photoelectric conversion layers by facilitating easy adjustment of optical properties such as refractive index of the transparent electroconductive film that are related to a difference in refractive indices between photoelectric conversion layers and the transparent electroconductive film.

Another object of the present invention is to provide a transparent electroconductive film having superior adhesion to a photoelectric conversion layer serving as a base that exhibits little change over time.

Another object of the present invention is to provide a composition for a transparent electroconductive film for forming the aforementioned transparent electroconductive film, and a multi-junction solar cell that uses the transparent electroconductive film.

### Means for Solving the Problems

The inventors of the present invention conducted extensive studies on a transparent electroconductive film provided between the photoelectric conversion layers of a multi-junction solar cell. As result, it was found that a transparent electroconductive film can be produced that satisfies various requirements, such as favorable phototransmittance, high electrical conductivity and low refractive index, required during use in a multi-junction solar cell by a wet coating method consisting of using a coating material to form a coated film having fine particles as a main component thereof, impregnating a dispersion containing a binder into this coated film and baking, or forming a coated film having as a main component thereof a component in which fine particles and a binder are compounded, and baking this coated film. In addition, it was also found that running costs for producing the transparent electroconductive film can be reduced since vacuum deposition is not used in this method. In addition, the inventors of the present invention also found that this method offers the advantage of facilitating the adjustment of optical properties such as refractive index of the transparent electroconductive film as relating to a difference in refractive indices between the photoelectric conversion layers and the transparent electroconductive film by adjusting the coating material, or the ratio at which it is incorporated and the like, that is used in the wet coating method, while also having found that improvement of the performance of a multi-junction solar cell, which was unable to be achieved in the case of producing using a vacuum deposition method, can be realized by optimizing light reflection properties between the photoelectric conversion layers.

In addition, it was found that, in the case of employing a bilayar structure consisting of an electroconductive fine particle layer and a binder layer, adhesion with an amorphous silicon layer serving as a base is superior to that of a single transparent electroconductive films, and that by employing a state in which the electroconductive fine particle layer is impregnated with the binder layer, there is little change in the film over time.

In a first aspect of the present invention, the transparent electroconductive film for a solar cell thereof is a transparent electroconductive film for a solar cell that is provided between photoelectric conversion layers of a multi-junction solar cell, wherein the electroconductive film is formed in a state in which a fine particle layer is impregnated with a binder layer by using a wet coating method to impregnate and bake a dispersion containing a binder (to be referred to as a binder dispersion) into a coated film of fine particles formed by coating a dispersion containing electroconductive fine particles (to be referred to as an electroconductive fine particle dispersion) using a wet coating method, or the electroconductive film is formed by baking a coated film obtained by coating a composition for a transparent electroconductive film containing electroconductive fine particles and a binder using a wet coating method, the electroconductive component in the base material that composes the electroconductive film is present within the range of 5 to 95% by weight, and the thickness of the electroconductive film is within the range of 5 to 200 nm.

In a second aspect of the present invention, the transparent electroconductive film for a solar cell thereof is characterized in that the binder in the dispersion containing the binder and the binder in the composition for a transparent electroconductive film is cured by heating within the range of 100 to 400° C. or by irradiating with ultraviolet light.

In a third aspect of the present invention, the transparent electroconductive film for a solar cell thereof is characterized in that the binder contains one or more types of an acrylic resin, acrylate resin, polycarbonate resin, polyester resin, alkyd resin, polyurethane resin, acrylurethane resin, polystyrene resin, polyacetal resin, polyamide resin, polyvinyl alcohol resin, polyvinyl acetate resin, cellulose resin, ethyl cellulose resin, epoxy resin, vinyl chloride resin, siloxane polymer or metal alkoxide hydrolysate (including a sol gel).

In a fourth aspect of the present invention, the transparent electroconductive film for a solar cell thereof is characterized in that the transparent electroconductive film contains one type or two or more types selected from the group consisting of a silane coupling agent, aluminate coupling agent and titanate coupling agent.

In a fifth aspect of the present invention, the transparent electroconductive film for a solar cell thereof is characterized in that the electroconductive fine particles are first fine particles composed of an oxide, hydroxide or composite compound of one type or two or more types of elements selected from the group consisting of Zn, In, Sn, Sb, Si, Al, Ga, Co, Mg, Ca, Sr, Ba, Ce, Ti, Y and Zr, or a mixture of two or more types thereof.

In a sixth aspect of the present invention, the transparent electroconductive film for a solar cell thereof is characterized in that the electroconductive fine particles are second fine particles composed of nanoparticles consisting of a mixed alloy containing one type or two or more types of elements selected from the group consisting of C, Si, Cu, Ni, Ag, Pd, Pt, Au, Ru, Rh and Ir.

In a seventh aspect of the present invention, the transparent electroconductive film for a solar cell thereof is characterized in that the electroconductive fine particles are a mixture of both the first fine particles and the second fine particles.

In an eighth aspect of the present invention, the transparent electroconductive film for a solar cell thereof is characterized in that the wet coating method is any of a spray coating method, dispenser coating method, spin coating method, knife coating method, slit coating method, inkjet coating method, gravure printing method, screen printing method, offset printing method or die coating method.

In a ninth aspect of the present invention, the transparent electroconductive film for a solar cell thereof is characterized in that the refractive index of the transparent electroconductive film formed is 1.1 to 2.0.

The multi-junction solar cell of the present invention has the transparent electroconductive film for a solar cell of the present invention provided between photoelectric conversion layers.

The composition for a transparent electroconductive film of the present invention comprises:

electroconductive fine particles composed of:

first fine particles composed of an oxide, hydroxide or composite compound of one type or two or more types of elements selected from the group consisting of Zn, In, Sn, Sb, Si, Al, Ga, Co, Mg, Ca, Sr, Ba, Ce, Ti, Y and Zr, or mixture of two or more types thereof, and

second fine particles composed of nanoparticles consisting of a mixed alloy containing one type or two or more types of elements selected from the group consisting of C, Si, Cu, Ni, Ag, Pd, Pt, Au, Ru, Rh and Ir;

a binder that is one or more types of any of an acrylic resin, acrylate resin, polycarbonate resin, polyester resin, alkyd resin, polyurethane resin, acrylurethane resin, polystyrene resin, polyacetal resin, polyamide resin, polyvinyl alcohol resin, polyvinyl acetate resin, cellulose resin, ethyl cellulose resin, epoxy resin, vinyl chloride resin, siloxane polymer or metal alkoxide hydrolysate (including a sol gel), and is cured by heating within the range of 100 to 400° C. or by irradiating with ultraviolet light; and,

a dispersion medium.

### Effects of the Invention

The present invention enables the production of a transparent electroconductive film by a wet coating method using a coating material that satisfies each of the requirements of favorable phototransmittance, high electrical conductivity, low refractive index and the like required when using in a multi-junction solar cell. Moreover, the present invention offers the advantage of being able to reduce running costs during production of a transparent electroconductive film by using a process that does not use vacuum deposition.

In addition, the present invention offers an additional advantage of being able to optimize light reflection properties between photoelectric conversion layers since optical properties, such as the refractive index of the transparent electroconductive film as related to the difference in refractive indices between the photoelectric conversion layers and the transparent electroconductive film, can be easily adjusted. Moreover, since the transparent electroconductive film of the present invention is composed of two layers consisting of an electroconductive fine particle layer and a binder layer, it also offers the advantages of superior adhesion with an amorphous silicon layer serving as a base as well as little change over time in comparison with single transparent electroconductive films.

### BRIEF DESCRIPTION OF THE DRAWINGS

FIG. 1 is a schematic drawing of a multi-junction solar cell.

FIG. 2 is a drawing schematically representing a cross-section of a transparent electroconductive film prior to baking.

### EMBODIMENTS OF THE INVENTION

The following provides an explanation of embodiments of the present invention based on the drawings.

The transparent electroconductive film for a solar cell of the present invention is provided between photoelectric conversion levers of a multi-junction solar cell. As shown in FIG, 1, a multi-junction solar cell has a front side electrode layer 12 formed on a transparent substrate 11, and an amorphous silicon layer 13 as a first photoelectric conversion layer formed on this electrode layer 12. A transparent electroconductive film 14 is formed on the amorphous silicon layer 13, and a microcrystalline silicon layer 15 as a second photoelectric conversion layer is formed on this transparent electroconductive film 14, resulting in a structure in which the transparent electroconductive film 14 is interposed between the two photoelectric conversion layers 13 and 15. Moreover, a back side electrode layer 16 is formed an the microcrystalline silicon layer 15.

The transparent electroconductive film 14 of the present invention is formed by coating an electro-conductive fine particle dispersion using a wet coating method to form a fine particle coated film, and impregnating a binder dispersion onto the coated film using a coating method followed by baking, or coating a composition for a transparent electroconductive film containing electroconductive fine particles and a binder using a wet coating method followed by baking the resulting coated film. An electroconductive component is present in a base material that composes the transparent electroconductive film within the range of 5 to 95% by weight, and the thickness of the electroconductive film is within the range of 5 to 200 nm. Here, the form of the electroconductive component changes as a result of electroconductive fine particles contained in the electroconductive fine particle dispersion being baked, while the base material is composed having as a main component thereof a binder dispersion or a residual component of the binder after baking contained in the composition for a transparent electroconductive film.

In the case the transparent electroconductive film 14 is formed by a vacuum deposition method such as sputtering, since the refractive index of the film is determined by the material of a target material, it is difficult to obtain a refractive index suitable for use as an intermediate film provided between photoelectric conversion layers of a solar cell, and the refractive index tends to be high. On the other hand, in the case of a transparent electroconductive film formed using a wet coating method, since the transparent electroconductive film is typically formed by coating and baking a composition for a transparent electroconductive film, which is a mixture of electroconductive fine particles, binder and other components, a desired low refractive index is obtained for the film formed using a wet coating method by adjusting the components of the composition. The transparent electroconductive film 14 of the present invention is formed by baking in the manner described above, and by having not only an electroconductive component, but also a base material present in this transparent electroconductive film 14, the refractive index of light can be lowered as compared with films produced by a process using a vacuum deposition method such as sputtering. On the basis of the above, there is the advantage of being able to reduce running costs. Moreover, use of a coating material offers the additional advantage of being able to easily adjust optical properties such as the refractive index of the transparent electroconductive film as related to the difference in refractive indices between the photoelectric conversion layers and the transparent electroconductive film.

An example of a transparent electroconductive film formed using a wet coating method is a single transparent electroconductive film in which a composition prepared by containing both electroconductive fine particles and a binder component is coated followed by baking thereof. In this single transparent electroconductive film as well, since a configuration is employed in which both an electroconductive component and a base material are present in the film, the refractive index of light can be lowered as compared with films produced by a process using a vacuum deposition method such as sputtering.

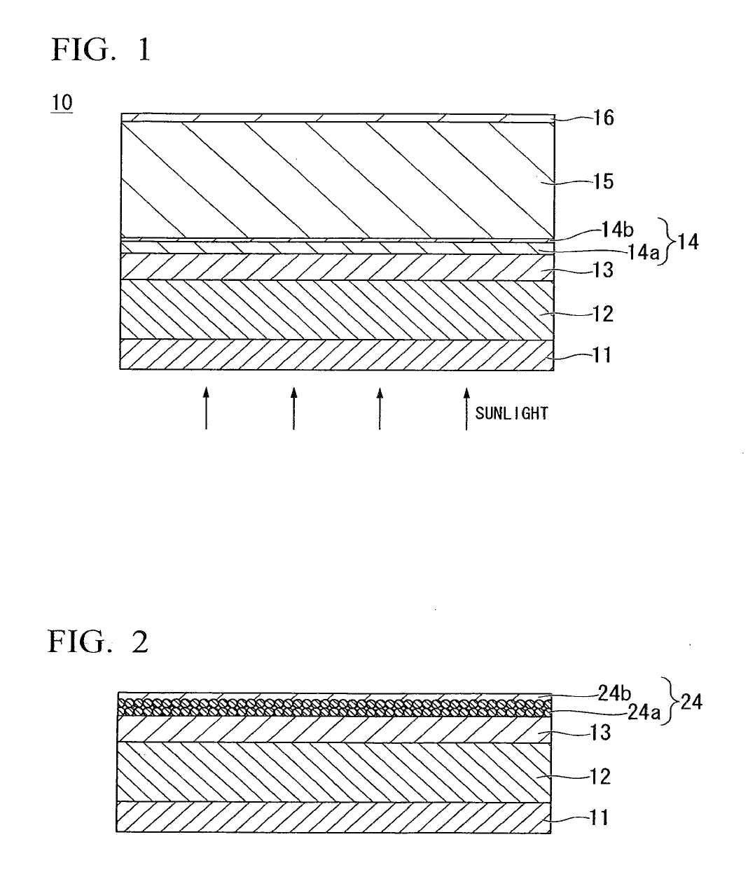

On the other hand, the transparent electroconductive film 14 of the present invention is formed by first forming a coated film by coating an electroconductive fine particle dispersion not containing a binder on a photoelectric conversion layer in the form of the amorphous silicon layer 13, and coating a binder dispersion not containing electroconductive fine particles onto this electroconductive fine particle layer, followed by baking at a prescribed temperature. Namely, as shown in FIG. 1, the transparent electroconductive film 14 of the present indention has a binder layer 14b not containing electroconductive fine particles formed for an upper layer. In addition, a lower layer in the vicinity of the interface with the amorphous silicon layer 13 is composed of an electroconductive fine particle layer 14a of which all or a portion of the surface thereof is covered with the binder layer 14b and in which a portion thereof is impregnated by coating a binder dispersion. This electroconductive fine particle layer 14a secures high electrical conductivity as a result of a portion of the particles being sintered by baking.

As a result of being composed in the manner described above, the transparent electroconductive film 14 of the present invention not only offers the advantages of a single transparent electroconductive film formed by a composition collectively containing electroconductive fine particles and a binder exponent, but else offers the advantages of having superior adhesion with a base in the form of an amorphous silicon layer as compared with a single transparent electroconductive film, as well as demonstrating little change over time since all or a portion of the surface of the electroconductive fine particle layer 14a is formed in a state of being covered by the binder layer 14b.

The reason for defining the ratio of the electroconductive component of the base material to be within the aforementioned range is that, if the ratio is less than the lower limit value, adequate electrical conductivity is not obtained, while if the upper limit value is exceeded, adhesion between the photoelectric conversion layers contacted by the upper and lower layers is unable to be adequately obtained. In addition, it becomes difficult to adjust the refractive index to a desired refractive index if outside the aforementioned range. The ratio of the electroconductive component in the base material is preferably 5 to 95% by weight and more preferably 30 to 85% by weight.

Here, the reason for defining the film thickness to be within the aforementioned range is that film thickness is also an element that is capable of adjusting refractive index, and makes it possible to increase the difference in refractive index with the microcrystalline silicon layer. The film thickness is preferably 20 to 100 nm. The thickness of the transparent electroconductive film as referred to here is the total thickness that results from combining the thickness of the electroconductive fine particle layer 14a and the thickness of the binder layer 14b.

The refractive index of the transparent electroconductive film 14 in the present invention is preferably adjusted to 1.1 to 2.0. If adjusted to within this range, the difference in refractive index with the microcrystalline silicon layer can be increased, only short wavelength light can be selectively and efficiently reflected, and transmission of long wavelength light can be made to be favorable. The refractive index is particularly preferably 1.3 to 1.8.

The composition for a transparent electroconductive film used to form the transparent electroconductive film relating to the present invention can contain electroconductive fine particles and a binder, the electroconductive fine particles and the binder can be dispersed in a dispersion medium, and can be composed of two liquids consisting of an electroconductive fine particle dispersion that forms the electroconductive fine particle layer 14a and a binder dispersion that forms the binder layer 14b.

The electroconductive fine particle dispersion that forms the electroconductive fine particle layer 14a is a composition in which electroconductive fine particles and other required components are dispersed in a dispersion medium. The binder dispersion that forms the binder layer 14b is a composition in which a binder component and other required components are dispersed in a dispersion medium.

Although there are no particular limitations on the type thereof, first fine particles, composed of an oxide, hydroxide or composite compound of one type or two or more types of elements selected from the group consisting of Zn, In, Sn, Sb, Si, Al, Ga, Co, Mg, Ca, Sr, Ba, Ce, Ti, Y and Zr, or a mixture of two or more types thereof, can be used for the electroconductive fine particles used in the electroconductive fine particle dispersion. Among these, tin oxide powder, zinc oxide powder or a compound in which these are doped with one type or two or more types of metal is used preferably. Examples include ITO powder (indium-doped tin oxide), ZnO powder, ATO powder (antimony-doped tin oxide), AZO powder (aluminum-doped zinc oxide), IZO powder (indium-doped zinc oxide) and TZO powder (tantalum-doped zinc oxide).

In addition, second fine particles composed of nanoparticles consisting of a mixed alloy containing one type or two or more types of elements selected from the group consisting of C, Si, Cu, Ni, Ag, Pd, Pt, Au, Ru, Rh and Ir may be also be used for the electroconductive fine particles.

Moreover, a mixture of the first fine particles and the second fine particles at a desired ratio may also be used for the electroconductive fine particles.

In addition, the content ratio of electroconductive fine particles present in the solid fraction contained in the electroconductive fine particle dispersion is preferably within the range of 50 to 99% by weight. The reason for making the content ratio of the electroconductive fine particles to be within the above range is that, if it is less than the lower limit value thereof, electrical conductivity of the electroconductive fine particle layer decreases, while if it exceeds the upper limit value, adhesion of the electroconductive fine particle layer formed decreases. The content ratio of the electroconductive fine particles is particularly preferably within the range of 70 to 90% by weight. In addition, the average particle diameter of the electroconductive fine particles is preferably within the range of 10 to 100 nm, and particularly preferably within the range of 20 to 60 nm, in order to maintain stability in the dispersion medium.

The type and ratio of the electroconductive fine particles used is suitably selected according to various conditions such as the configuration of the target multi-junction solar cell or the difference in refractive indices between the photoelectric conversion layers and the transparent electroconductive film.

A binder that is cured by heating within a range of 100 to 400° C. or by irradiating with ultraviolet light is used for the binder contained in the composition for a transparent electroconductive film and the binder dispersion. If the heating temperature at which the binder is cured is within the above range, components originating in the binder remain within the transparent electroconductive film formed by baking the coated film and are able to compose the main component of the base material.

Specific examples of types of binders include acrylic resin, acrylate resin, polycarbonate resin, polyester resin, alkyd resin, polyurethane resin, acrylurethane resin, polystyrene resin, polyacetal resin, polyamide resin, polyvinyl alcohol resin, polyvinyl acetate resin, cellulose resin, ethyl cellulose resin, epoxy resin, vinyl chloride resin, siloxane polymer obtained by hydrolyzing an alkoxy silane and metal alkoxide hydrolysate (including a sol gel), and one type or a combination of two or more types of these binders that satisfy the aforementioned conditions can be used.

Addition of a type of binder as described above makes it possible to form a transparent electroconductive film having a low haze rate and volume resistivity at low temperatures, lower the resistivity of the transparent electroconductive film, and adjust the refractive index of the transparent electroconductive film formed.

The content ratio of these binders is preferably within the range of 5 to 50% by weight as the ratio of solid fraction in the composition for a transparent electroconductive film or the binder dispersion. The reason for making the binder content ratio to be within the above range is that, if the binder content ratio is less than the lower limit value thereof, electrical conductivity of the transparent electroconductive film formed decreases, while if the content ratio exceeds the upper limit value, adhesion of the transparent electroconductive film formed decreases. The binder content ratio is particularly preferably within the range of 10 to 30% by weight.

There are no particular limitations on the type of dispersion medium used in the electroconductive fine particle dispersion and the binder dispersion, and examples include water, alcohols such as methanol, ethanol, isopropanol, butanol or hexanol, ketones such as acetone, methyl ethyl ketone, methyl isobutyl ketone, cyclohexanone, isophorone or 4-hydroxy-4-methyl-2-pentanone, hydrocarbons such as toluene, xylene, hexane or cyclohexane, amides such as N,N-dimethylformamide or N,N-dimethylacetoamide, sulfoxides such as dimethylsulfoxide, glycols such as ethylene glycol and glycol ethers such as ethyl cellosolve. In addition, two or more types of these dispersion media can also be used as a mixture.

The content ratio of the dispersion medium in the electroconductive fine particle dispersion is preferably within the range of 80 to 99% by weight in order to obtain favorable film deposition performance. On the other hand, the content ratio of the dispersion medium in the binder dispersion is preferably within the range of 50 to 99.99% by weight.

A coupling agent is preferably added to the electroconductive fine particle dispersion corresponding to other components used. This is added in order to improve bindability between the electroconductive fine particles and the binder as well as improve adhesion between the electroconductive fine particle layer formed by this electroconductive fine particle dispersion and the photoelectric conversion layers. Examples of coupling agents include a silane coupling agents, aluminate coupling agents and titanate coupling agents, and one type of two or more types thereof may be used.

Examples of silane coupling agents that can be used include vinyltriethoxysilane, γ-glycidoxypropyltrimethoxysilane and γ-methacryloxypropyltrimethoxysilane.

In addition, examples of aluminate coupling agents that can be used include an aluminate coupling agent containing an acetoalkoxy group as represented by the following formula (1).

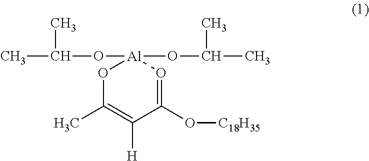

In addition, examples of titanate compound agents that can be used include isopropyl triisostearoyl titanate, isopropyl tridecylbenzene sulfonyl titanate, isopropyl tris(dioctylpyrophosphate) titanate, tetraisopropyl bis(dioctylphosphate) titanate, tetraoctyl bis(ditridecylphosphate) titanate, tetra(2,2-diallyloxymethyl-1-butyl) bis(di-tridecyl) phosphate titanate, bis(dioctylpyrophosphate) oxyacetate titanate and tris(dioctylpyrophosphate) ethylene titanate,

In the case a titanate coupling agent is hydrolyzable (as in the case of tetraalkoxytitanates, for example), it can also be used as hydrolysis or condensation product. Among these, preferable organic titanium compounds consist of tetraalkoxytitanates and titanate coupling agents represented by the following structural formulas (2) to (8).

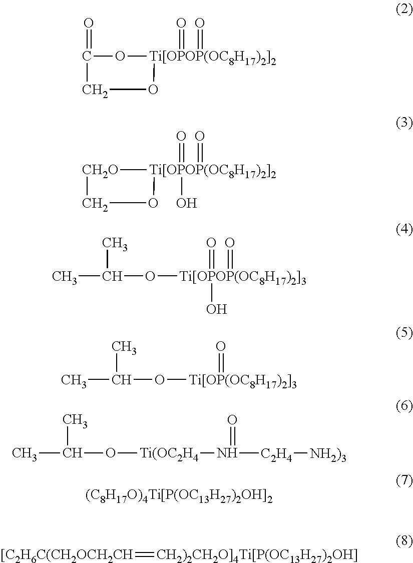

The content ratio of coupling agent is preferably within the range of 0.2 to 50% by weight based on the ratio of solid fraction present in the electroconductive fine particle dispersion. If the content ratio is below the lower limit value of the above range, the effect of adding coupling agent is not adequately obtained, while if the content ratio exceeds the upper limit value, a decrease in electrical conductivity is brought about due to inhibition of bonding between fine particles by the coupling agent. A content ratio of 0.5 to 2% by weight is particularly preferable.

In addition, arbitrary additives such as a surfactant or pH adjuster can be further contained in the composition for a transparent electroconductive film and binder dispersion of the present invention corresponding to the components used. Examples of these additives include surfactants (such as cationic, anionic or nonionic surfactants), and pH adjusters (such as organic acids, inorganic acids, ex, formic acid, acetic acid, propionic acid, butyric acid, octylic acid, hydrochloric acid, nitric acid, perchloric acid etc., and amines).

The content ratio of surfactant in the case of containing a surfactant is preferably 0.5 to 2.0% by weight based on the electroconductive powder, while the content ratio of pH adjuster in the case of containing a pH adjuster is preferably 0.5 to 2.0% by weight based on the electroconductive powder.

The electroconductive fine particle dispersion is prepared by mixing electroconductive fine particles and a dispersion medium at a desired ratio, or by mixing after adding the aforementioned coupling agents or other arbitrary additives as necessary followed by uniformly dispersing the fine particles in the mixture using a bead mill and the like.

Next, an explanation is provided of a production method of the multi-junction solar cell of the present invention.

First, as shown in FIG. 1, the transparent substrate 11 is prepared, and the front side electrode layer 12 is formed on this substrate. Examples of materials that can be used for the transparent substrate 11 include a glass plate, acrylic resin and carbonate. A substance that is transparent and has electrical conductivity such as ITO, SnO₂, ZnO or AZO is used for the front side electrode layer 12 formed. Furthermore, there are no particular limitations on the method used to form the front side electrode layer 12, and it may be formed using a conventionally known method. Furthermore, since glass substrates 11 are commercially available on which a transparent film having electrical conductivity is formed, such commercially available products may also be used.

Next, the amorphous silicon layer 13 is formed on the transparent substrate 11 on which the front side electrode layer 12 has been formed. There are no particular limitations on the method used to form this amorphous silicon layer 13, and it may be formed using a conventionally known method such as plasma CVD.

Next, as shown in FIG. 2, a coated film 24a of electroconductive fine particles is formed on a base material on which the amorphous silicon layer 13 is provided by coating the previously described electroconductive fine particle dispersion by a wet coating method, This coated film 24a is then dried a temperature of 20 to 120° C. and preferably 25 to 60° C. for 1 to 30 minutes and preferably for 2 to 10 minutes.

Next, the aforementioned binder dispersion is impregnated into the coated film 24a of electroconductive fine particles by a wet coating method, and coated so as to cover all or a portion of the surface of the coated film 24a of the electroconductive fine particles with a coated film 24b of the binder dispersion. In addition, the coating here is preferably carried out so that the weight of the binder component in the coated binder dispersion is a weight ratio of 0.5 to 10 baaed on the total weight of the electroconductive fine particles contained in the coated film of electroconductive fine particles (weight of binder component in the coated binder dispersion/weight of the electroconductive fine particles). If the weight ratio is less than the lower limit value of the above range, it becomes difficult to obtain adequate adhesion, while if the weight ratio exceeds the upper limit value, surface resistance increases easily. The weight ratio is particularly preferably 0.5 to 3. This coated film 24b is dried at a temperature of 20 to 120° C. and preferably 25 to 60° C. for 1 to 30 minutes and preferably for 2 to 10 minutes. Coating of the electroconductive fine particle dispersion and binder dispersion is carried out so that the thickness of the transparent electroconductive film formed after baking is 5 to 200 nm end preferably 20 to 100 nm. Here, the reason for coating the electroconductive fine particle dispersion and binder dispersion so that the thickness of the transparent electroconductive film after baking is 5 to 200 nm is that if the thickness is less than the lower limit value of the above range, it becomes difficult to form a uniform film, while if the thickness exceeds the upper limit value, the amount of material used increases to beyond that which is necessary thereby resulting in waste. In this manner, a transparent electroconductive coated film 24 is formed composed of the coated film 24a of the electroconductive fine particles and the coated film 24b of the binder dispersion.

Alternatively, the previously described composition for a transparent electroconductive film is coated onto a base material on which is provided the amorphous silicon layer 13 by a wet coating method. Here, coating is carried out so that the thickness after baking is 5 to 200 nm and preferably 20 to 100 nm. Continuing, this coated film is dried at a temperature of 20 to 120° C. and preferably 25 to 60° C. for 1 to 30 minutes and preferably 2 to 10 minutes. A transparent electroconductive film is formed in this manner.

Although the wet coating method is particularly preferably any of spray coating, dispenser coating, spin coating, knife coating, slit coating, inkjet coating, gravure printing, screen printing, offset printing or die coating can be used. However, there are no particular limitations thereon.

Spray coating is a method in which a dispersion is coated onto a base material in the form of a mist using compressed air or the dispersion itself is pressurized to form a mist that is then coated onto a base material, while dispenser coating is a method in which, for example, a dispersion is placed in a syringe and the dispersion is charged from a narrow nozzle on the end of the syringe by pressing the piston of the syringe to coat onto a base material. Spin coating is a method in which a dispersion is dropped onto a rotating base material, and the dropped dispersion spreads to the edges of the base material by the centrifugal force of that rotation, while knife coating is a method in which a base material provided at a prescribed interval from the tip of a knife is movably provided in the horizontal direction, and a dispersion is supplied from the knife onto a base material on the upstream side followed by moving the base material horizontally towards the downstream side. Slit coating is a method in which a dispersion is allowed to flow out from a narrow slit and be coated onto a base material, while inkjet coating is a method in which a dispersion is filled into an ink cartridge of a commercially available inkjet printer followed by inkjet printing the dispersion onto a base material. Screen printing is a method in which silk gauze is used as a pattern indicator, and a dispersion is transferred to a base material by passing through a block image formed thereon. Offset printing is a printing method that utilizes the water repellency of ink in which a dispersion affixed to a block is transferred from the block to a rubber sheet without being directly adhered to a base material and then transferring from the rubber sheet to the base material. Die coating is a method in which a dispersion supplied to a die is distributed with a manifold and extruded onto a thin film through a slit followed by coating onto the surface of a moving base material. The die coating method consists of slot coating, slide coating and curtain coating methods.

Next, the base material having the transparent electroconductive coated film 24 is baked by holding at 130 to 400° C. and preferably 150 to 350° C. for 5 to 60 minutes and preferably 15 to 40 minutes in air or in an inert gas atmosphere of nitrogen or argon and the like. As a result, the transparent electroconductive coated film 24 shown in FIG. 2 is baked hard, and the transparent electroconductive film 14 on the amorphous silicon layer 13 is formed as shown in FIG. 1. In this case, the transparent electroconductive film 14 is formed in a state in which the electroconductive fine particle layer 14a is impregnated with the binder layer 14b.

The reason for defining the baking temperature to be within the range of 130 to 400° C. is that, if the baking temperature is lower than 130° C., the problem results in which the surface resistance value of the transparent electroconductive film becomes excessively high. In addition, if the baking temperature exceeds 400° C., the advantage in terms of production of being a low-temperature process is no longer acquired. Namely, this is because production cost increases and productivity decreases. In addition, amorphous silicon, microcrystalline silicon and hybrid silicon solar cells in which they are used are particularly susceptible to heat, thereby resulting in the baking step causing a decrease in conversion efficiency.

Moreover, the reason for defining the baking time of the base material having the coated film to be within the above range is that, if the baking time is less than the lower limit value of that range, sintering of the fine particles becomes inadequate thereby resulting in the problem of being unable to obtain adequate electrical conductivity, while if the baking time exceeds the upper limit value of the above range, a decrease in power generation performance occurs due to excessive heating of the amorphous silicon layer.

The transparent electroconductive film 14 of the present invention can be formed in the manner described above. By employing a wet coating method in which a coating material (composition for a transparent electroconductive film: electroconductive fine particle dispersion and binder dispersion) is used, and a coated film having for a main component thereof a component in which fine particles and binder have been compounded is formed followed by baking the coated film, a transparent electroconductive film can be produced that satisfies various requirements such as favorable phototransmittance, high electrical conductivity and low refractive index required when using a multi-junction solar cell, while also making it possible to reduce running costs during production of the transparent electroconductive film as a method that does not use vacuum deposition.

In addition, the coating material (composition for a transparent electroconductive film) used in the wet coating method offers the advantage of facilitating adjustment of optical properties such as the refractive index of the transparent electroconductive film as related to the difference in refractive indices between the photoelectric conversion layers and the transparent electroconductive film by adjusting the ratio at which it is incorporated and the like, thereby making it possible to realize improved performance of a multi-junction solar cell unable to be achieved when producing by vacuum deposition by optimizing light reflection properties between the photoelectric conversion layers.

Next, the microcrystalline silicon layer 15 is formed on the transparent electroconductive film 14. There are no particular limitations on the method used to form this microcrystalline silicon layer 15, and it may be formed with a conventionally known method such as plasma CVD.

Finally, a multi-junction solar cell 10 is obtained by forming the back side electrode layer 16 on the microcrystalline silicon layer 15. In this multi-junction thin film solar cell 10, the transparent substrate 11 is the light receiving side.

The following provides a detailed explanation of examples of the present invention along with comparative examples.

### EXAMPLE 1

First, a square piece of glass measuring 10 cm on a side was prepared for the transparent substrate 11, and SnO₂ was used for the front side electrode layer 12. The film thickness of the front side electrode layer 12 at this time was 800 nm, the sheet resistance was 10 Ω/□, and the haze rate was 15 to 20%. Next, the amorphous silicon layer 13 was deposited onto the front side electrode layer 12 at a thickness of 300 nm using plasma CVD.

Next, a composition for a transparent electroconductive film composed of an electroconductive fine particle dispersion and a binder dispersion was prepared in the manner described below.

As shown in Table 1, 1.0 part by weight of ITO powder having an atomic ratio Sn/(Sn+In) of 0.1 and a particle diameter of 0.03 μm was added as electroconductive fine particles, and 0.01 part by weight of the organic titanate coupling agent represented by the aforementioned formula (3) was added as coupling agent followed by the addition of ethanol as dispersion medium to bring to a total of 100 parts by weight.

Furthermore, the average particle diameter of the electroconductive fine particles was measured by calculating from the number average as described below. First, electron micrographs of the target fine particles were taken. A SEM or TEM was suitably used for the electron microscope used for imaging according to the size of particle diameter and the type of powder. Next, the diameter of about 1000 of each particle was measured from the resulting electron micrographs to obtain frequency distribution data. A value of 50% for the cumulative frequency (D50) was used for the average particle diameter.

The fine particles in the mixture were dispersed by placing the mixture in a die mill (horizontal bead mill) and operating for 2 hours using zirconia beads having a diameter of 0.3 mm to obtain an electroconductive fine particle dispersion.

In addition, 1.0 part by weight of a siloxane polymer obtained by hydrolyzing ethyl silicate was prepared as binder, and ethanol was added as dispersion medium to a total of 100 parts by weight to obtain a binder dispersion.

Continuing, the resulting electroconductive fine particle dispersion was coated onto the amorphous silicon layer 13 to a film thickness of the fine particle layer of 80 nm by spin Coating, followed by drying for 5 minutes at a temperature of 50° C. to form a coated film of the electroconductive fine particles.

Next, the resulting binder dispersion was impregnated onto the coated film of the electroconductive fine particles to a film thickness after baking of 90 nm by spin coating, followed by drying for 5 minutes at a temperature of 50° C. to form a transparent electroconductive coated film. The film thickness of the fine particle layer after forming the transparent electroconductive coating layer was measured from cross-sectional electron micrographs obtained by SEM. The binder dispersion was coated so that the weight of the binder component in the binder dispersion was at a weight ratio shown in the following Table 1 based on the total weight of the fine particles contained in the coated film of the coated electroconductive fine particles (ratio of the weight of the binder component in the binder dispersion/weight of the electroconductive fine particles and the coupling agent).

Moreover, the transparent electroconductive film 14 was deposited by baking the transparent electroconductive coated film for 30 minutes at 100° C. In addition, the film thickness of the transparent electroconductive film obtained by baking was measured from cross-sectional electron micrographs obtained by SEM. The ratio of fine particles to binder in the transparent electroconductive film obtained by baking (fine particles/binder) was 1/1. Furthermore, the temperature during baking was conditioned on the average temperature being within ±5° of the set temperature as determined by measuring the temperatures at four locations on the square glass plate measuring 10 cm on a side.

Continuing, the microcrystalline silicon layer 15 is deposited on the transparent electroconductive film 14 at a thickness of 1.7 μm using plasma CVD, and a ZnO film having a thickness of 80 nm and an Ag film having a thickness of 300 nm were respectively deposited as a back side electrode layer 16 by sputtering.

A multi-junction thin film silicon solar cell produced in this manner was then irradiated with light having an AM value of 1.5 as incident light at an optical luminosity of 100 mW/cm², followed by measuring the short-circuit current density end conversion efficiency at that time. Furthermore, the values for short-circuit current density and conversion efficiency of Example 1 were assigned a value of 1.0, and the values of short-circuit current density and conversion efficiency in the subsequent Examples 2 to 50 and Comparative Examples 1 to 5 were expressed as relative values based on the values of Example 1. In addition, refractive indices at a wavelength of 600 nm of the transparent electroconductive film 14 of the multi-junction thin film silicon solar cells were measured by preliminarily inputting film thicknesses observed in SEM cross-sections using a spectroscopic ellipsometer (M-2000D1, J. A. Woollam Japan) and analysis software “WVASE32” provided with the apparatus. Those results are shown in the following Table 4.

### EXAMPLE 2

As shown in Table 1, a multi-junction thin film silicon solar cell was produced and evaluated in the same manner as Example 1 with the exception of using an electroconductive fine particle dispersion obtained by adding 0.5 parts by weight of ITO ponder having an atomic ratio Sb/(Sb+In) of 0.05 and a particle diameter of 0.02 μm as electroconductive fine particles and adding 0.01 part by weight of the titanate coupling agent represented by the aforementioned formula (3) as coupling agent followed by adding ethanol as dispersion medium to bring to a total of 100 parts by weight, using a binder dispersion obtained by preparing 0.2 parts by weight of a siloxane polymer as a binder and adding ethanol as a dispersion medium to bring to a total of 100 parts by weight, forming a coated film of electroconductive fine particles by coating the electroconductive fine particle dispersion to a film thickness of the fine particle layer of 20 nm by spin coating, and impregnating the binder dispersion onto the coated film of electroconductive fine particles to a film thickness after baking of 20 nm by spin coating. Furthermore, the ratio of fine particles to binder in the transparent electroconductive film at this time was 5/2. Those results are shown in the following Table 4.

### EXAMPLE 3

As shown in Table 1, a multi-junction thin film silicon solar cell was produced and evaluated in the same manner as Example 1 with the exception of using an electroconductive fine particle dispersion obtained by adding 1.0 part by weight of PTO powder (P-doped SnO₂) having an atomic ratio P/(P+Sn) of 0.1 and a particle diameter of 0.02 μm as electroconductive fine particles and adding 0.02 parts by weight of the titanate coupling agent represented by the aforementioned formula (2) as coupling agent followed by adding ethanol as dispersion medium to bring to a total of 100 parts by weight, forming a coated film of electroconductive fine particles by coating the electroconductive fine particle dispersion to a film thickness of the fine particle layer of 70 nm by spin coating, and impregnating a binder dispersion onto the coated film of electroconductive fine particles to a film thickness after baking of 70 nm by spin coating. Furthermore, the ratio of fine particles to binder in the transparent electroconductive film at this time was 1/1. Those results are shown in the following Table 4.

### EXAMPLE 4

As shown in Table 1, a multi-junction thin film silicon solar cell was produced and evaluated in the same manner as Example 1 with the exception of using an electroconductive fine particle dispersion obtained by adding 1.5 parts by weight of ATO powder having an atomic ratio Sb/(Sb+Sn) of 0.1 and a particle diameter of 0.03 μm as electroconductive fine particles and adding 0.02 parts by weight of the aluminate coupling agent represented by the aforementioned formula (1) as coupling agent followed by adding ethanol as dispersion medium to bring to a total of 100 parts by weight, using a binder dispersion obtained by preparing 1.2 parts by weight of a siloxane polymer as a binder and adding ethanol as a dispersion medium to bring to a total of 100 parts by weight, forming a coated film of electroconductive fine particles by coating the electroconductive particle dispersion to a film thickness of the fine particle layer of 120 nm by spin coating, and impregnating the binder dispersion onto the coated film of electroconductive fine particles to a film thickness after baking of 120 nm by spin coating. Furthermore, the ratio of fine particles to binder in the transparent electroconductive film at this time was 15/12. Those results are shown in the following Table 4.

### EXAMPLE 5

As shown in Table 1, a multi-junction thin film silicon solar cell was produced and evaluated in the same manner is Example 1 with the exception of using an electroconductive fine particle dispersion obtained by adding 1.2 parts by weight of ZnO powder having a particle diameter of 0.03 μm as electroconductive fine particles and adding 0.03 parts by weight of vinyltriethoxysilane as coupling agent followed by adding ethanol as dispersion medium to bring to a total of 100 parts by weight, using a binder dispersion obtained by preparing 0.5 parts by weight of acrylic resin as a binder and adding ethanol as dispersion medium to bring to a total of 100 parts by weight, forming a coated film of electroconductive fine particles by coating the electroconductive fine particle dispersion to a film thickness of the fine particle layer of 80 nm by spin coating, and impregnating the binder dispersion onto the coated film of electroconductive fine particles to a film thickness after baking of 80 nm by spin coating. Furthermore, the ratio of fine particles to binder in the transparent electroconductive film at this time was 3/5. Those results are shown in the following Table 4.

### EXAMPLE 6

As shown in Table 1, a multi-junction thin film silicon solar cell was produced and evaluated in the same manner as Example 1 with the exception of using an electroconductive fine particle dispersion obtained by adding 0.8 parts by weight of AZO powder having an atomic ratio Al/(Al+Zn) of 0.1 and a particle diameter of 0.03 μm as electroconductive fine particles and adding 0.01 part by weight of the titanate coupling agent represented by the aforementioned formula (4) as coupling agent followed by adding ethanol as dispersion medium to bring to a total of 100 parts by weight, using a binder dispersion obtained by preparing parts by weight of a cellulose resin as a binder and adding butyl carbitol acetate as dispersion medium to bring to a total of 100 parts by weight, forming a coated film of electroconductive fine particles by coating the electroconductive fine particle dispersion to a film thickness of the fine particle layer of 60 nm by spin coating, and impregnating the binder dispersion onto the coated film of electroconductive fine particles to a film thickness after baking of 80 nm by spin coating. Furthermore, the ratio of fine particles to binder in the transparent electroconductive film at this time was 12/3. Those results are show in the following Table 4.

### EXAMPLE 7

As shown in Table 1, a multi-junction thin film silicon solar cell was produced and evaluated in the same manner as Example 1 with the exception of using an electroconductive fine particle dispersion obtained by adding 1.5 parts by weight of ITO powder having an atomic ratio Sn/(Sn+In) of 0.05 and a particle diameter of 0.02 μm as electroconductive fine particles and adding 0.01 part by weight of the γ-methacryloxypropyltrimethoxysilane as coupling agent followed by adding ethanol as dispersion medium to bring to a total of 100 parts by weight, using a binder dispersion obtained by preparing 0.9 parts by weight of epoxy resin as a binder and adding toluene as a dispersion medium to bring to a total of 100 parts by weight, forming a coated film of electroconductive fine particles by coating the electroconductive fine particle dispersion to a film thickness of the fine particle layer of 100 nm by spin coating, and impregnating the binder dispersion onto the coated film of electroconductive fine particles to a film thickness after baking of 100 nm by spin coating. Furthermore, the ratio of fine particles to binder in the transparent electroconductive film at this time was 15/9. Those results are shown in the following Table 4.

### EXAMPLE 8

As shown in Table 1, a multi-junction thin film silicon solar cell was produced and evaluated in the same manner as Example 1 with the exception of using an electroconductive fine particle dispersion obtained by adding 1.2 parts by weight of ATO powder having an atomic ratio Sb/(Sb+Sn) of 0.05 and a particle diameter of 0.02 μm as electroconductive fine particles and adding 0.02 parts by weight of the titanate coupling agent represented by the aforementioned formula (5) as coupling agent followed by adding ethanol as dispersion medium to bring to a total of 100 parts by weight, using a binder dispersion obtained by preparing 1.0 part by weight of polyester resin as a binder and adding xylene as a dispersion medium to bring to a total of 100 parts by weight, forming a coated film of electroconductive fine particles by coating the electroconductive fine particle dispersion to a film thickness of the fine particle layer of 80 nm by spin coating, and impregnating the binder dispersion onto the coated film of electroconductive fine particles to a film thickness after baking of 80 nm by spin coating. Furthermore, the ratio of fine particles to binder in the transparent electroconductive film at this time 12/10. Those results are shown in the following Table 1.

### EXAMPLE 9

As shown in Table 1, a multi-junction thin film silicon solar cell was produced and evaluated in the same manner as Example 1 with the exception of using an electroconductive fine particle dispersion obtained by adding 2.0 parts by weight of PTO (P-doped SnO₂) powder having an atomic ratio P/(P+Sn) of 0.05 and a particle diameter of 0.03 μm as electroconductive fine particles and adding 0.05 parts by weight of γ-glycidoxypropyltrimethoxysilane as coupling agent followed by adding ethanol as dispersion medium to bring to a total of 100 parts by weight, using a binder dispersion obtained by preparing 1.1. parts by weight of an acrylurethane resin as a binder and adding isophorone as a dispersion medium to bring to a total of 100 parts by weight, forming a coated film of electroconductive fine particles by coating the electroconductive fine particle dispersion to a film thickness of the fine particle layer of 140 nm by spin coating, end impregnating the binder dispersion onto the coated film of electroconductive fine particles to a film thickness after baking of 140 nm by spin coating. Furthermore, the ratio of fine particles to binder in the transparent electro-conductive film at this time was 20/11. Those results are shown in the following Table 4.

### EXAMPLE 10

As shown in Table 1, a multi-junction thin film silicon solar cell was produced and evaluated in the same manner as Example 1 with the exception of using a composition for a transparent electroconductive film obtained by adding 0.8 parts by weight of MgO powder a particle diameter of 0.03 μm as electroconductive fine particles and adding 0.02 parts by weight of the titanate coupling agent represented by the aforementioned formula (4) as coupling agent followed by adding ethanol as dispersion medium to bring to a total of 100 parts by weight, using a binder dispersion obtained by preparing 1.0 part by weight of polystyrene resin as a binder and adding cyclohexanone as a dispersion medium to bring to a total of 100 parts by weight, forming a coated film of electroconductive fine particles by coating the electroconductive fine particle dispersion to a film thickness of the fine particle layer of 70 nm by spin coating, and impregnating the binder dispersion onto the coated film of electroconductive fine particles to a film thickness after baking of 100 nm by spin coating. Furthermore, the ratio of fine particles to binder in the transparent electroconductive film at this time was 8/10. Those results are shown in the following Table 4.

### EXAMPLE 11

As shown in Table 1, a multi-junction thin film silicon solar cell was produced and evaluated in the same manner as Example 1 with the exception of using an electroconductive fine particle dispersion obtained by adding 2.0 parts by weight of TiO₂ powder having a particle diameter of 0.02 μm as electroconductive fine particles and adding 0.02 parts by weight of the titanate coupling agent represented by the aforementioned formula (6) as coupling agent followed by adding ethanol as dispersion medium to bring to a total of 100 parts by weight, using a binder dispersion obtained by preparing 1,5 part by weight of polyvinyl acetate resin as a binder and adding toluene as a dispersion medium to bring to a total of 100 parts by weight, forming a coated film of electroconductive fine particles by coating the electroconductive fine particle dispersion to a film thickness of the fine particle layer of 120 nm by spin coating, and impregnating binder dispersion onto the coated film of electroconductive fine particles to a film thickness after baking of 120 nm by spin coating. Furthermore, the ratio of fine particles to binder in the transparent electroconductive film at this time was 20/15. Those results are shown in the following Table 4.

### EXAMPLE 12

As shown in Table 1, a multi-junction thin film silicon solar cell was produced and evaluated in the same manner as Example 1 with the exception of using an electroconductive fine particle dispersion obtained by adding 1.0 part by weight of Ag powder having a particle diameter of 0.03 μm as electroconductive fine particles and adding 0.01 part by weight of of the titanate coupling agent represented by the aforementioned formula (7) as coupling agent followed by adding ethanol as dispersion medium to bring to a total of 100 parts by weight, using a binder dispersion obtained by preparing 1.0 part by weight of polyvinyl alcohol resin as a binder and adding ethanol as a dispersion medium to bring to a total of 100 parts by weight, forming a coated film of electroconductive fine particles by coating the electroconductive fine particle dispersion to a film thickness of the fine particle layer of 70 nm by spin coating, and impregnating the binder dispersion onto the coated film of electroconductive fine particles to a film thickness after baking of 80 nm by spin coating. Furthermore, the ratio of fine particles to binder in the transparent electroconductive film at this time was 1/1. Those results are shown in the following Table 4.

### EXAMPLE 13

As shown in Table 1, a multi-function thin film silicon solar cell was produced and evaluated in the same manner as Example 1 with the exception of using an electroconductive fine particle dispersion obtained by adding 0.8 parts by weight of Ag—Pd alloy powder having a ratio of Ag/Pd of 9/1 and a particle diameter of 0.02 μm as electroconductive fine particles and adding 0.01 part by weight of the titanate coupling agent represented by the aforementioned formula (7) as coupling agent followed by adding ethanol as dispersion medium to bring to a total of 100 parts by weight, using a binder dispersion obtained by preparing 0.8 parts by weight of siloxane polymer as a binder and adding ethanol as a dispersion medium to bring to a total of 100 parts by weight, forming a coated film of electroconductive fine particles by coating the electroconductive fine particle dispersion to a film thickness of the fine particle layer of 50 nm by spin coating, and impregnating the binder dispersion onto the coated film of electroconductive fine particles to a film thickness after baking of 50 nm by spin coating. Furthermore, the ratio of fine particles to binder in the transparent electroconductive film at this time was 8/8. Those results are shown in the following Table 4.

### EXAMPLE 14

As shown in Table 1, a multi-junction thin film silicon solar cell was produced and evaluated in the same manner as Example 1 with the exception of using an electroconductive fine particle dispersion obtained by adding 1.0 part by weight of Au powder having a particle diameter of 0.02 μm as electroconductive fine particles and adding 0.01 part by weight of the titanate coupling agent represented by the aforementioned formula (8) as coupling agent followed by adding ethanol as dispersion medium to bring to a total of 100 parts by weight, using a binder dispersion obtained by preparing 1.2 parts by weight of polyamide resin as a binder and adding xylene as a dispersion medium to bring to a total of 100 parts by weight, forming a coated film of electroconductive fine particles by coating the electroconductive fine particle dispersion to a film thickness of the fine particle layer of 80 nm by spin coating, and impregnating the binder dispersion onto the coated film of electroconductive fine particles to a film thickness after baking of 110 nm by spin coating. Furthermore, the ratio of fine particles to binder in the transparent electroconductive film at this time was 10/12. Those results are shown in the following Table 4.

### EXAMPLE 15

As shown in Table 1, a multi-junction thin film silicon solar cell was produced and evaluated in the same manner as Example 1 with the exception of using an electroconductive fine particle dispersion obtained by adding 1.2 parts by weight of Ru ponder having a particle diameter of 0.03 μm as electroconductive fine particles and adding 0.03 parts by weight of the titanate coupling agent represented by the aforementioned formula (8) as coupling agent followed by adding ethanol as dispersion medium to bring to a total of 100 parts by weight, using a binder dispersion obtained by preparing 1.2 parts by weight of vinyl chloride resin as a binder and adding xylene as a dispersion medium to bring to a total of 100 parts by weight, forming a coated film of electroconductive fine particles by coating the electroconductive fine particle dispersion to a film thickness of the fine particle layer of 90 nm by spin coating, and impregnating the binder dispersion onto the coated film of electroconductive fines particles to a film thickness after baking of 100 nm by spin coating. Furthermore, the ratio of fine particles to binder in the transparent electroconductive film at this time was 12/12. Those results are shown in the following Table 4.

### EXAMPLE 16

As shown in Table 1, a multi-junction thin film silicon solar cell was produced and evaluated in the same manner as Example 1 with the exception of using an electroconductive fine particle dispersion obtained by adding 1.0 part by weight of Rh powder having a particle diameter of 0.03 μm as electroconductive fine particles and adding 0.02 parts by weight of the titanate coupling agent represented by the aforementioned formula (8) as coupling agent followed by adding ethanol as dispersion medium to bring to a total of 100 parts by weight, using a binder dispersion obtained by preparing 0.8 parts by weight of acrylate resin as a binder and adding ethanol as a dispersion medium to bring to a total of 100 parts by weight, forming a coated film of electroconductive fine particles by coating the electroconductive fine particle dispersion to a film thickness of the fine particle layer of 80 nm by spin coating, and impregnating the binder dispersion onto the coated film of electroconductive fine particles to a film thickness after baking of 80 nm by spin coating. Furthermore, the ratio of fine particles to binder in the transparent electroconductive film at this time was 10/8. Those results are shown in the following Table 4

### EXAMPLE 17

As shown in Table 1, a multi-junction thin film silicon solar cell was produced and evaluated in the same manner as Example 1 with the exception of using an electroconductive fine particle dispersion obtained by adding 1.0, part by weight of ITO powder having an atomic ratio of Sb/(Sb+In) of 0.1 and a particle diameter of 0.03 μm as electroconductive fine particles and adding 0.02 parts by weight of the titanate coupling agent represented by the aforementioned formula (3) as coupling agent followed by adding ethanol as dispersion medium to bring to a total of 100 parts by weight, using a binder dispersion obtained by preparing 1.0 part by weight of polycarbonate resin as a binder and adding toluene as a dispersion medium to bring to a total of 100 parts by weight, forming a coated film of electroconductive fine particles by coating the electroconductive fine particle dispersion to a film thickness of the fine particle layer of 60 nm by spin coating, and impregnating the binder dispersion onto the coated film of electroconductive fine particles to a film thickness after baking of 80 nm by spin coating. Furthermore, the ratio of fine particles to binder in the transparent electroconductive film at this time was 10/10. Those results are shown in the following Table 4.

### EXAMPLE 18

As shown in Table 2, a multi-junction thin film silicon solar cell was produced and evaluated in the same manner as Example 1 with the exception of using an electroconductive fine particle dispersion obtained by adding 1.0 part by weight of PTO (P-doped SnO₂) powder having an atomic ratio of P/(P+Sn) of 0.1 and a particle diameter of 0.02 μm as electroconductive fine particles and adding 0.01 part by weight of the titanate coupling agent represented by the aforementioned formula (3) as coupling agent followed by adding ethanol as dispersion medium to bring to a total of 100 parts by weight, using a binder dispersion obtained by preparing 0.8 parts by weight of alkyd resin as a binder and adding cyclohexanone as a dispersion medium to bring to a total of 100 parts by weight, forming a coated film of electroconductive fine particles by coating the electroconductive fine particle dispersion to a film thickness of the fine particle layer of 80 nm by spin coating, and impregnating the binder dispersion onto the coated film of electroconductive fine particles to a film thickness after baking of 100 nm by spin coating. Furthermore, the ratio of fine particles to binder in the transparent electroconductive film at this time was 10/8. Those results are shown in the following Table 4.

### EXAMPLE 19

As shown in Table 2, a multi-junction thin film silicon solar cell was produced and evaluated in the same manner as Example 1 with the exception of using an electroconductive fine particle dispersion obtained by adding 1.0 part by weight of ATO powder having an atomic ratio of Sb/(Sb+Sn) of 0.1 and a particle diameter of 0.03 μm as electroconductive fine particles and adding 0.02 parts by weight of the titanate coupling agent represented by the aforementioned formula (3) as coupling agent followed by adding ethanol as dispersion medium to bring to a total of 100 parts by weight, using a binder dispersion obtained by preparing 1.2 parts by weight of polyurethane fiber as a binder and adding xylene as a dispersion medium to bring to a total of 100 parts by weight, forming a coated film of electroconductive fine particles by coating the electroconductive fine particle dispersion to a film thickness of the fine particle layer of 80 nm by spin coating, and impregnating the binder dispersion onto the coated film of electroconductive fine particles to a film thickness after baking of 80 nm by spin coating. Furthermore, the ratio of fine particles to binder in the transparent electroconductive film. at this time was 10/12. Those results are shown in the following Table 4.

### EXAMPLE 20

As shown in Table 2, a multi-junction thin film silicon solar cell was produced and evaluated in the same manner as Example 1 with the exception of using an electroconductive fine particle dispersion obtained by adding 1.0 part by weight of ITO powder having an atomic ratio of Sb/(Sb+In) of 0.05 and a particle diameter of 0.02 μm as electroconductive fine particles and adding 0.01 part by weight of the titanate coupling agent represented by the aforementioned formula (2) as coupling agent followed by adding ethanol as dispersion medium to bring to a total of 100 parts by weight, and using a binder dispersion obtained by preparing parts by weight of polyacetal resin as a binder and adding hexane as a dispersion medium to bring to a total of 100 parts by weight. Furthermore, the ratio of fine particles to binder in the transparent electroconductive film at this time was 10/8. Those results are shown in the following Table 4.

### EXAMPLE 21

As shown in Table 2, a multi-junction thin film silicon solar cell was produced and evaluated in the same manner as Example 1 with the exception of using an electroconductive fine particle dispersion obtained by adding 1.0 part by weight of ATO powder having an atomic ratio of Sb/(Sb+Sn) of 0.05 and a particle diameter of 0.03 μm as electroconductive fine particles and adding 0.02 parts by weight of the titanate coupling agent represented by the aforementioned formula (2) as coupling agent followed by adding ethanol as dispersion medium to bring to a total of 100 parts by weight, using a binder dispersion obtained by preparing 1.0 parts by weight of ethyl cellulose resin as a binder and adding hexane as a dispersion medium to bring to a total of 100 parts by weight, forming a coated film of electroconductive fine particles by coating the electroconductive fine particle dispersion to a film thickness of the fine particle layer of 80 nm by spin coating, and impregnating the binder dispersion onto the coated film of electroconductive fine particles to a film thickness after baking of 100 nm by spin coating, Furthermore, the ratio of fine particles to binder in the transparent electroconductive film at this time was 10/10. Those results are shown in the following Table 4.

### EXAMPLE 22

As shown in Table 2, a multi-junction thin film silicon solar cell was produced and evaluated in the same manner as Example 1 with the exception of using an electroconductive fine particle dispersion obtained by adding 1.0 part by weight of PTO (P-doped SnO₂) powder having an atomic ratio of P/(P+Sn) of 0.05 and a particle diameter of 0.02 μm as electroconductive fine particles and adding 0.01 part by weight of the titanate coupling agent represented by the aforementioned formula (2) as coupling agent followed by adding ethanol as dispersion medium to bring to a total of 100 parts by weight, using a binder dispersion obtained by preparing 1.0 part by weight of a methoxyhydrolysate of Al as a binder and adding methanol as a dispersion medium to bring to a total of 100 parts by weight, forming a coated film of electroconductive fine particles by coating the electroconductive fine particle dispersion to a film thickness of the fine particle layer of 70 nm by spin coating, and impregnating the binder dispersion onto the coated film of electroconductive fine particles to a film thickness after baking of 70 nm by spin coating. Furthermore, the ratio of fine particles to binder in the transparent electroconductive film at this time was 10/10. Those results are shown in the following Table 4.

### EXAMPLE 23

As shown in Table 2, a multi-junction thin film silicon solar cell was produced and evaluated in the same manner as Example 1 with the exception of using an electroconductive fine particle dispersion obtained by adding 1.0 part by weight of ATO powder having an atomic ratio of Sb/(Sb+Sn) of 0.1 and a particle diameter of 0.02 μm as electroconductive fine particles and adding 0.02 parts by weight of the titanate coupling agent represented by the aforementioned formula (4) as coupling agent followed by adding ethanol as dispersion medium to bring to a total of 100 parts by weight, using a binder dispersion obtained by preparing 1.0 part by weight of a mixture of alkyd resin and polyamide resin mixed at a ratio of 7:3 as a binder and adding isophorone as a dispersion medium to bring to a total of 100 parts by weight, forcing a coated film of electroconductive fine particles by coating the electroconductive fine particle dispersion to a film thickness of the fine particle layer of 70 nm by spin coating, and impregnating the binder dispersion onto the coated film of electroconductive fine particles to a film thickness after baking of 90 nm by spin coating. Furthermore, the ratio of fine particles to binder in the transparent electroconductive film at this time was 10/10. Those results are shown in the following Table 4.

### EXAMPLE 24

As shown Table 2, a multi-junction thin film silicon solar cell was produced and evaluated in the same manner as Example 1 with the exception of using an electroconductive fine particle dispersion obtained by adding 1.0 part by weight of Si powder having a particle diameter of 0.02 μm as electroconductive fine particles and adding 0.01 part by weight of γ-methacryloxypropyltrimethoxysilane as coupling agent followed by adding ethanol as dispersion medium to bring to a total of 100 parts by weight, using a binder dispersion obtained by preparing 1.0 part by weight, of siloxane polymer as a binder and adding ethanol as a dispersion medium to bring to a total of 100 parts by weight, forming a coated film of electroconductive fine particles by coating the electroconductive fine particle dispersion to a film thickness of the fine particle layer of 80 nm by spin coating, and impregnating the binder dispersion onto the coated film of electroconductive fine particles to a film thickness after baking of 80 nm by spin coating. Furthermore, the ratio of fine particles to binder in the transparent electroconductive film at this time was 10/10. Those results are shown in the following Table 4.

### EXAMPLE 25

As shown in Table 2, a multi-junction thin film silicon solar cell was produced and evaluated in the same manner as Example 1 with the exception of using an electroconductive fine particle dispersion obtained by adding 1.0 part by weight of Ga powder having a particle diameter of 0.03 μm as electroconductive fine particles and adding 0.01 part by weight of the titanate coupling agent represented by the aforementioned formula (2) as coupling agent followed by adding ethanol as dispersion medium to bring to a total of 100 parts by weight, using a binder dispersion obtained by preparing 1.0 part by weight of alkyd resin as a binder and adding cyclohexanone as a dispersion medium to bring to a total of 100 parts by weight, forming a coated film of electroconductive fine particles by coating the electroconductive fine particle dispersion to a film thickness of the fine particle layer of 80 nm by spin coating, and impregnating the binder dispersion onto the coated film of electroconductive fine particles to a film thickness after baking of 100 nm by spin coating, Furthermore, the ratio of fine particles to binder in the transparent electroconductive film at this time was 10/10. Those results are shown in the following Table 4.

### EXAMPLE 26

As shown in Table 2, a multi-junction thin film silicon solar cell was produced and evaluated in the same manner as Example 1 with the exception of using an electroconductive fine particle dispersion obtained by adding 1.0 part by weight off Co powder having a particle diameter of 0.02 μm as electroconductive fine particles and adding 0.01 part by weight of the titanate coupling agent represented by the aforementioned formula (2) as coupling agent followed by adding ethanol as dispersion medium to bring to a total of 100 parts by weight, using a binder dispersion obtained by preparing 1.0 part by weight of ethyl cellulose resin as a binder and adding hexane as a dispersion medium to bring to a total of 100 parts by weight, forming a coated film of electroconductive fine particles by coating the electroconductive fine particle dispersion to a film thickness of the fine particle layer of 80 nm by spin coating, and impregnating the binder dispersion onto the coated film of electroconductive fine particles to a film thickness after baking of 80 nm by spin coating. Furthermore, the ratio of fine particles to binder in the transparent electroconductive film at this time was 10/10. Those results are shown in the following Table 4.

### EXAMPLE 27

shown in Table 2, a multi-junction thin film silicon solar cell was produced and evaluated in the same manner as Example 1 with the exception of using an electroconductive fine particle dispersion obtained by adding 1.0 part by weight of Ca powder having a particle diameter of 0.02 μm as electroconductive fine particles and adding 0.01 part by weight of the titanate coupling agent represented by the aforementioned formula (3) as coupling agent followed by adding ethanol as dispersion medium to bring to a total of 100 parts by weight, and using a binder dispersion obtained by preparing 1.0 part by weight of polycarbonate resin as a binder and adding toluene as a dispersion medium to bring to a total of 100 parts by weight. Furthermore, the ratio of fine particles to binder in the transparent electroconductive film at this time was 10/10. Those results are shown in the following Table 4.

### EXAMPLE 28

As shown in Table 2, a multi-junction thin film silicon solar cell was produced and evaluated in the same manner as Example 1 with the exception of using an electroconductive fine particle dispersion obtained by adding 1.0 part by weight of Sr powder having a particle diameter of 0.03 μm as electroconductive fine particles and adding 0.01 part by weight of the titanate coupling agent represented by the aforementioned formula (3) as coupling agent followed by adding ethanol as dispersion medium to bring to a total of 100 parts by weight, using a binder dispersion obtained by preparing 1.0 part by weight of polyacetal resin as a binder and adding hexane as a dispersion medium to bring to a total of 100 parts by weight, forming a coated film of electroconductive fine particles by coating the electroconductive fine particle dispersion to a film thickness of the fine particle layer of 80 nm by spin coating, and impregnating the binder dispersion onto the coated film of electroconductive fine particles to a film thickness after baking of 100 nm by spin coating. Furthermore, the ratio of fine particles to binder in the transparent electroconductive film at this time was 10/10. Those results are shown in the following Table 4.

### EXAMPLE 23

As shown in Table 2, a multi-junction thin film silicon solar cell was produced and evaluated in the same manner as Example 1 with the exception of using an electroconductive fine particle dispersion obtained by adding 1.0 part by weight of Ba(OH)₂ powder having a particle diameter of 0.02 μm as electroconductive fine particles and adding 0.01 part by weight of the titanate coupling agent represented by the aforementioned formula (4) as coupling agent followed by adding ethanol as dispersion medium to bring to a total of 100 parts by weight, using a binder dispersion obtained by preparing 1.0 part by weight of polyurethane resin as a binder and adding xylene as a dispersion medium to bring to a total of 100 parts by weight, forming a coated film of electroconductive fine particles by coating the electroconductive fine particle dispersion to a film thickness of the fine particle layer of 80 nm by spin coating, and impregnating the binder dispersion onto the coated film of electroconductive fine particles to a film thickness after baking of 80 nm by spin coating. Furthermore, the ratio of fine particles to binder in the transparent electroconductive film at this time was 10/10. Those results are shown in the following Table 4.

### EXAMPLE 30

As shown in Table 2, a multi-junction thin film silicon solar cell was produced and evaluated in the same manner as Example 1 with the exception of using an electroconductive fine particle dispersion obtained by adding 1.0 part by weight of Ce powder having a particle diameter of 0.03 μm as electroconductive fine particles and adding 0.01 part by weight of the titanate coupling agent represented by the aforementioned formula (4) as coupling agent followed by adding ethanol as dispersion medium to bring to a total of 100 parts by weight, using a binder dispersion obtained by preparing 1.0 part by weight of polyamide resin as a binder and adding xylene as a dispersion medium to bring to a total of 100 parts by weight, forming a coated film of electroconductive fine particles by coating the electroconductive fine particle dispersion to a film thickness of the fine particle layer of 80 nm by spin coating, and impregnating the binder dispersion onto the coated film of electroconductive fine particles to a film thickness after baking of 100 nm by spin coating. Furthermore, the ratio of fine particles to binder in the transparent electroconductive film at this time was 10/10. Those results are shown in the following Table 4.

### EXAMPLE 31

As shown in Table 2, a multi-junction thin film silicon solar cell was produced and evaluated in the same manner as Example 1 with the exception of using an electroconductive fine particle dispersion obtained by adding 1.0 part by weight of Y powder having a particle diameter of 0.03 μm as electroconductive fine particles and adding 0.01 part by weight of the titanate coupling agent represented by the aforementioned formula (5) as coupling agent followed by adding ethanol as dispersion medium to bring to a total of 100 parts by weight, using a binder dispersion obtained by preparing 1.0 part by weight of siloxane polymer as a binder and adding ethanol as a dispersion medium to bring to a total of 100 parts by weight, forming a coated film of electroconductive fine particles by coating the electroconductive fine particle dispersion to a film thickness of the fine particle layer of 80 nm by spin coating, and impregnating the binder dispersion onto the coated film of electroconductive fine particles to a film thickness after baking of 100 nm by spin coating. Furthermore, the ratio of fine particles to binder in the transparent electroconductive film at this time was 10/10. Those results are shown in the following Table 4.

### EXAMPLE 32

As shown in Table 2, a multi-junction thin film silicon solar cell was produced and evaluated in the same manner as Example 1 with the exception of using an electroconductive fine particle dispersion obtained by adding 1.0 part by weight of Zr powder having a particle diameter of 0.02 μm as electroconductive fine particles and adding 0.01 part by weight of the titanate coupling agent represented by the aforementioned formula (5) as coupling agent followed by adding ethanol as dispersion medium to bring to a total of 100 parts by weight, using a binder dispersion obtained by preparing 1.0 part by weight of alkyd resin as a binder and adding cyclohexanone as a dispersion medium to bring to a total of 100 parts by weight, forming a coated film of electroconductive fine particles by coating the electroconductive fine particle dispersion to a film thickness of the fine particle layer of 80 nm by spin coating, and impregnating the binder dispersion onto the coated film of electroconductive fine particles to a film thickness after baking of 80 nm by spin coating. Furthermore, the ratio of fine particles to binder in the transparent electroconductive film at this time was 10/10. Those results are shown in the following Table 4.

### EXAMPLE 33

As shown in Table 2, a multi-junction thin film silicon solar cell was produced and evaluated in the same manner as Example 1 with the exception of using an electroconductive fine particle dispersion obtained by adding 1.0 part by weight of Sn(OH)₂ powder having a particle diameter of 0.02 μm as electroconductive fine particles and adding 0.01 part by weight of the titanate coupling agent represented by the aforementioned formula (6) as coupling agent followed by adding ethanol as dispersion medium to bring to a total of 100 parts by weight, and using a binder dispersion obtained by preparing 1.0 part by weight of ethyl cellulose resin as a binder and adding hexane as a dispersion medium to bring to a total of 100 parts by weight. Furthermore, the ratio of fine particles to binder in the transparent electroconductive film at this time was 10/10. Those results are shown in the following Table 4.

### EXAMPLE 34

As shown in Table 2, a multi-junction thin film silicon solar cell was produced and evaluated in the same manner as Example 1 with the exception of using an electroconductive fine particle dispersion obtained by adding 1.0 part by weight of a powder of MgO and ZnO₂ mixed at a ratio of 5.5 and having a particle diameter of 0.03 μm as electroconductive fine particles and adding 0.01 part by weight of the titanate coupling agent represented by the aforementioned formula (6) as coupling agent followed by adding ethanol as dispersion medium to bring to a total of 100 parts by weight, using a binder dispersion obtained by preparing 1.0 part by weight of polycarbonate resin as a binder and adding toluene as a dispersion medium to bring to a total of 100 parts by weight, forming a coated film of electroconductive fine particles by coating the electroconductive fine particle dispersion to a film thickness of the fine particle layer of 80 nm by spin coating, and impregnating the binder dispersion onto the coated film of electroconductive fine particles to a film thickness after baking of 80 nm by spin coating. Furthermore, the ratio of fine particles to binder in the transparent electroconductive film at this time was 10/10. Those results are shown in the following Table 4.

### EXAMPLE 35

As shown in Table 3, a multi-junction thin film silicon solar cell was produced and evaluated in the same manner as Example 1 with the exception of using an electroconductive fine particle dispersion obtained by adding 1.0 part by weight of C powder having a particle diameter of 0.03 μnm as electroconductive fine particles and adding 0.01 part by weight of the titanate coupling agent represented by the aforementioned formula (7) as coupling agent followed by adding ethanol as dispersion medium to bring to a total of 100 parts by weight, using a binder dispersion obtained by preparing 1.0 part by weight of polyacetal resin as a binder and adding hexane as a dispersion medium to bring to a total of 100 parts by weight, forming a coated film of electroconductive fine particles by coating the electroconductive fine particle dispersion to a film thickness of the fine particle layer of 80 nm by spin coating, and impregnating the binder dispersion onto the coated film of electroconductive fine particles to a film thickness after baking of 100 nm by spin coating. Furthermore, the ratio of fine particles to binder in the transparent electroconductive film at this time was 10/10. Those results are shown in the following Table 4.

### EXAMPLE 36

As shown in Table 3, a multi-junction thin film silicon solar cell was produced and evaluated in the same manner as Example 1 with the exception of using an electroconductive fine particle dispersion obtained by adding 1.0 part by weight of SiO₂ powder having a particle diameter of 0.01 μm as electroconductive fine particles and adding 0.01 part by weight of the titanate coupling agent represented by the aforementioned formula (7) as coupling agent followed by adding ethanol as dispersion medium to bring to a total of 100 parts by weight, and using a binder dispersion obtained by preparing 1.0 part by weight of polyurethane resin as a binder and adding xylene as a dispersion medium to bring to a total of 100 parts by weight, Furthermore, the ratio of fine particles to binder in the transparent electroconductive film at this time was 10/10. Those results are shown in the following Table 4.

### EXAMPLE 37

As shown in Table 3, a multi-junction thin film silicon solar cell was produced and evaluated in the same manner as Example 1 with the exception of using an electroconductive fine particle dispersion obtained by adding 1.0 part by weight of Cu powder having a particle diameter of 0.03 μm as electroconductive fine particles and adding 0.01 part by weight of the titanate coupling agent represented by the aforementioned formula (8) as coupling agent followed by adding ethanol as dispersion medium to bring to a total of 100 parts by weight, using a binder dispersion obtained by preparing 1.0 part by weight of polyamide resin as a binder and adding xylene as a dispersion medium to bring to a total of 100 parts by weight, forming a coated film of electroconductive fine particles by coating the electroconductive fine particle dispersion to a film thickness of the fine particle layer of 80 nm by spin coating, and impregnating the binder dispersion onto the coated film of electroconductive fine particles to a film thickness after baking of 80 nm by spin coating. Furthermore, the ratio of fine particles to binder in the transparent electroconductive film at this time was 10/10. Those results are shown in the following Table 4.

### EXAMPLE 38

As shown in Table 3, a multi-junction thin film silicon solar cell was produced and evaluated in the same manner as Example 1 with the exception of using an electroconductive fine particle dispersion obtained by adding 1.0 part by weight of Ni powder having a particle diameter of 0.03 μm as electroconductive fine particles and adding 0.01 part by weight of the titanate coupling agent represented by the aforementioned formula (8) as coupling agent followed by adding ethanol as dispersion medium to bring to a total of 100 parts by weight, using a binder dispersion obtained by preparing 1.0 part by weight of siloxane polymer as a binder and adding ethanol as a dispersion medium to bring to a total of 100 parts by weight, forming a coated film of electroconductive fine particles by coating the electroconductive fine particle dispersion to a film thickness of the fine particle layer of 80 nm by spin coating, and impregnating the binder dispersion onto the coated film of electroconductive fine particles to a film thickness after baking of 80 nm by spin coating. Furthermore, the ratio of fine particles to binder in the transparent electroconductive film at this time was 10/10. Those results are shown in the following Table 4.

### EXAMPLE 39

As shown in Table 3, a multi-junction thin film silicon solar cell was produced and evaluated in the same manner as Example 1 with the exception of using an electroconductive fine particle dispersion obtained by adding 1.0 part by weight of Pt powder having a particle diameter of 0.02 μm as electroconductive fine particles and adding 0.01 part by weight of the aluminate coupling agent represented by the aforementioned formula (1) as coupling agent followed by adding ethanol as dispersion medium to bring to a total of 100 parts by weight, using a binder dispersion obtained by preparing 1.0 part by weight of alkyd resin as a binder and adding cyclohexanone as a dispersion medium to being to a total of 100 parts by weight, forming a coated film of electroconductive fine particles by coating the electroconductive fine particle dispersion to a film thickness of the fine particle layer of 80 nm by spin coating, and impregnating the binder dispersion onto the coated film of electroconductive fine particles to a film thickness after baking of 100 nm by spin coating. Furthermore, the ratio of fine particles to binder in the transparent electroconductive film at this time was 10/10. Those results are shown in the following Table 4.

### EXAMPLE 40

As shown is Table 3, a multi-junction thin film silicon solar cell was produced and evaluated in the same manner as Example 1 with the exception of using an electroconductive fine particle dispersion obtained by adding 1.0 part by weight of Ir powder having a particle diameter of 0.03 μm as electroconductive fine particles and adding 0.01 part by weight of the aluminate coupling agent represented by the aforementioned formula (1) as coupling agent followed by adding ethanol as dispersion medium to bring to a total of 100 parts by weight, using a binder dispersion obtained by preparing 1.0 part by weight of ethyl cellulose resin as a binder and adding hexane as a dispersion medium to bring to a total of 100 parts by weight, forming a coated film of electroconductive fine particles by coating the electroconductive fine particle dispersion to a film thickness of the fine particle layer of 80 nm by spin coating, and impregnating the binder dispersion onto the coated film of electroconductive fine particles to a film thickness after baking of 100 nm by spin coating. Furthermore, the ratio of fine particles to binder in the transparent electroconductive film at this time was 10/10. Those results are shown in the following Table 4.

### EXAMPLE 41

As shown in Table 3, a multi-junction thin film silicon solar cell was produced and evaluated in the same manner as Example 1 with the exception of using an electroconductive fine particle dispersion obtained by adding 0.8 parts by weight of PTO powder (P-doped SnO₂) having an atomic ratio P/(P+Sn) of 0.1 and a particle diameter of 0.02 electroconductive fine particles and adding 0.01 part by weight of a mixture of the aluminate coupling agent represented by the aforementioned formula (1) and the titanate coupling agent represented by the aforementioned formula (3) mixed at a ratio of 5:5 as coupling agent followed by adding ethanol as dispersion medium to bring to a total of 100 parts by weight, using a binder dispersion obtained by preparing 1.0 part by weight of polycarbonate resin as a binder and adding toluene as a dispersion medium to bring to a total of 100 parts by weight, forming a coated film of electroconductive fine particles by coating the electroconductive fine particle dispersion to a film thickness of the fine particle layer of 80 nm by spin coating, and impregnating the binder dispersion onto the coated film of electroconductive fine particles to a film thickness after baking of 80 nm by spin coating. Furthermore, the ratio of fine particles to binder in the transparent electroconductive film at this time was 8/10. Those results are shown in the following Table 4.

### EXAMPLE 42

As shown in Table 3, a multi-junction thin film silicon solar cell was produced and evaluated in the same manner as Example 1 with the exception of using an electroconductive fine particle dispersion obtained by adding 1.2 parts by weight of ITO powder having an atomic ratio Sb/(Sb+In) of 0.1 and a particle diameter of 0.02 μm as electroconductive fine particles and adding 0.02 parts by weight of the titanate coupling agent represented by the aforementioned formula (3) as coupling agent followed by adding ethanol as dispersion medium to bring to a total of 100 parts by weight, using a binder dispersion obtained by preparing 1.0 part by weight of siloxane polymer as a binder and adding ethanol as a dispersion medium to bring to a total of 100 parts by weight, forming a coated film of electroconductive fine particles by coating the electroconductive fine particle dispersion to a film thickness of the fine particle layer of 100 nm by spray coating, and impregnating the binder dispersion, onto the coated film of electroconductive fine particles to a film thickness after baking of 120 nm by spray coating. Furthermore, the ratio of fine particles to binder in the transparent electroconductive film at this time was 12/10. Those results are shown in the following Table 4.

### EXAMPLE 43

As shown in Table 3, a multi-junction thin film silicon solar cell was produced and evaluated in the same manner as Example 1 with the exception of using an electroconductive fine particle dispersion obtained by adding 1.2 parts by weight of PTO powder having an atomic ratio P/(P+Sn) of 0.1 and a particle diameter of 0.03 μm as electroconductive fine particles and adding 0.02 parts by weight of the titanate coupling agent represented by the aforementioned formula (3) as coupling agent followed by adding ethanol as dispersion medium to bring to a total of 100 parts by weight, using a binder dispersion obtained by preparing 1.2 parts by weight of siloxane polymer as a binder and adding ethanol as a dispersion medium to bring to a total of 100 parts by weight, forming a coated film of electroconductive fine particles by coating the electroconductive fine particle dispersion to a film thickness of the fine particle layer of 100 nm by dispenser coating, and impregnating the binder dispersion onto the coated film of electroconductive fine particles to a film thickness after baking of 110 nm by dispenser coating. Furthermore, the ratio of fine particles to binder in the transparent electroconductive film at this time was 12/12. Those results are shown in the following Table 4.

### EXAMPLE 44

As shown in Table 3, a multi-junction thin film silicon solar cell was produced and evaluated in the same manner as Example 1 with the exception of using an electroconductive fine particle dispersion obtained by adding 1.2 parts by weight of ATO powder having an atomic ratio Sb/(Sb+Sn) of 0.1 and a particle diameter of 0.02 μm as electroconductive fine particles and adding 0.02 parts by weight of the titanate coupling agent represented by the aforementioned formula (3) as coupling agent followed by adding ethanol as dispersion medium to bring to a total of 100 parts by weight, using a binder dispersion obtained by preparing 0.8 parts by weight of siloxane polymer as a binder and adding ethanol is a dispersion medium to bring to a total of 100 parts by weight, forming a coated film of electroconductive fine particles by coating the electroconductive fine particle dispersion to a film thickness of the fine particle layer of 100 nm by knife coating, and impregnating the binder dispersion onto the coated film of electroconductive fine particles to a film thickness after baking of 100 nm by knife coating. Furthermore, the ratio of fine particles to binder in the transparent electroconductive film at this time was 12/8. These results are shown in the following Table 4.

### EXAMPLE 45

As shown in Table 3, a multi-junction thin film silicon solar cell was produced and evaluated in the same manner as Example 1 with the exception of using an electroconductive fine particle dispersion obtained by adding 1.2 parts by weight of ITO powder having an atomic ratio Sb/(Sb+In) of 0.05 and a particle diameter of 0.02 μm as electroconductive fine particles and adding 0.02 parts by weight of the titanate coupling agent represented by the aforementioned formula (2) as coupling agent followed by adding ethanol as dispersion medium to bring to a total of 100 parts by weight, using a binder dispersion obtained by preparing 1.2 parts by weight of siloxane polymer as a binder and adding ethanol as a dispersion medium to bring to a total of 100 parts by weight, forming a coated film of electroconductive fine particles by coating the electroconductive fine particle dispersion to a film thickness of the fine particle layer of 100 nm by slit coating, and impregnating the binder dispersion onto the coated film of electroconductive fine particles to a film thickness after baking of 100 nm by slit coating. Furthermore, the ratio of fine particles to binder in the transparent electroconductive film at this time was 12/12. Those results are shown in the following Table 4.

### EXAMPLE 46

shown in Table 3, a multi-junction thin film silicon solar cell was produced and evaluated in the same manner as Example 1 with the exception of using en electroconductive fine particle dispersion obtained by adding 1.0 part by weight of ATO powder having an atomic ratio Sb/(Sb+Sn) of 0.05 and a particle diameter of 0.03 μm as electroconductive fine particles and adding 0.01 part by weight of the titanate coupling agent represented by the aforementioned formula (2) as coupling agent followed by adding ethanol as dispersion medium to bring to a total of 100 parts by weight, using a binder dispersion obtained by preparing 1.0 part by weight of siloxane polymer as a binder and adding ethanol as a dispersion medium to bring to a total of 100 parts by weight, forming a coated film of electroconductive fine particles by coating the electroconductive fine particle dispersion to a film thickness of the fine particle layer of 90 nm by inkjet coating, and impregnating the binder dispersion onto the coated film of electroconductive fine particles to a film thickness after baking of 90 nm by inkjet coating. Furthermore, the ratio of fine particles to binder in the transparent electroconductive film at this time was 10/10. Those results are shown in the following Table 4.

### EXAMPLE 47

As shown in Table 3, a multi-junction thin film silicon solar cell was produced and evaluated in the same manner as Example 1 with the exception of using an electroconductive fine particle dispersion obtained by adding 5.0 parts by weight of PTO powder having an atomic ratio P/(P+Sn) of 0.05 and a particle diameter of 0.02 μm as electroconductive fine particles and adding 0.05 parts by weight of the titanate coupling agent represented by the aforementioned formula (2) as coupling agent followed by adding ethylene glycol as dispersion medium to bring to a total of 100 parts by weight, using a binder dispersion obtained by preparing 5.0 parts by weight of acrylic resin as a binder and adding ethylene glycol as a dispersion medium to bring to a total of 100 parts by weight, forming a coated film of electroconductive fine particles by coating the electroconductive fine particle dispersion to a film thickness of the fine particle layer of 120 nm by gravure printing, and impregnating the binder dispersion onto the coated film of electroconductive fine particles to a film thickness after baking of 120 nm by gravure printing. Furthermore, the ratio of fine particles to binder in the transparent electroconductive film at this time was 50/50. Those results are shown in the following Table 4.

### EXAMPLE 48

As shown in Table 3, a multi-junction thin film silicon solar cell was produced and evaluated in the same manner Example 1 with the exception of using an electroconductive fine particle dispersion obtained by adding 5.0 parts by weight of ATO powder having an atomic ratio Sb/(Sb+Sn) of 0.1 and a particle diameter of 0.02 μm as electroconductive fine particles and adding 0.05 parts by weight of the titanate coupling agent represented by the aforementioned formula (4) as coupling agent followed by adding ethylene glycol as dispersion medium to bring to a total of 100 parts by weight, using a binder dispersion obtained by preparing 5.0 parte by weight of ethyl cellulose resin as a binder and adding butyl carbitol acetate as a dispersion medium to bring to a total of 100 parts by weight, forming a coated film of electroconductive fine particles by coating the electroconductive fine particle dispersion to a film thickness of the fine particle layer of 160 nm by screen printing, and impregnating the binder dispersion onto the coated film of electroconductive fine particles to a film thickness after baking of 170 nm by screen printing. Furthermore, the ratio of fine particles to binder in the transparent electroconductive film at this time was 50/50. Those results are shown in the following Table 4.

### EXAMPLE 4

As shown in Tables 3, a multi-junction thin film silicon solar cell was produced and evaluated in the same manner as Example 1 with the exception of using as electroconductive fine particle dispersion obtained by adding 5.0 parts by weight of PTO (P-doped SnO₂) powder having an atomic ratio P/(P+Sn) of 0.1 and a particle diameter of 0.02 μm as electroconductive fine particles and adding ethylene glycol as dispersion medium to bring to a total of 100 parts by weight, using a binder dispersion obtained by preparing 5.0 parts by weight of alkyd resin as a binder and adding ethylene glycol as a dispersion medium to bring to a total of 100 parts by weight, forming a coated film of electroconductive fine particles by coating the electroconductive fine particle dispersion to a film thickness of the fine particle layer of 140 nm by offset printing, and impregnating the binder dispersion onto the coated film of electroconductive fine particles to a film thickness after baking of 150 nm by offset printing. Furthermore, the ratio of fine particles to binder in the transparent electroconductive film at this time 50/50. Those results are shown in the following Table 4.

### EXAMPLE 50

As shown in Table 3, a multi-junction thin film silicon solar was produced and evaluated in the same manner as Example 1 with the exception of using an electroconductive fine particle dispersion obtained by adding 1.0 part by weight of ATO powder having an atomic ratio Sb/(Sb+Sn) of 0.1 and a particle diameter of 0.02 μm as electroconductive fine particles and adding 0.01 part by weight of the titanate coupling agent represented by the aforementioned formula (3) as coupling agent followed by adding ethanol as dispersion medium to bring to a total of 100 parts by weight, using a binder dispersion obtained by preparing 0.8 parts by weight of siloxane polymer as a binder and adding ethanol as a dispersion medium to bring to a total of 100 parts by weight, forming a coated film of electroconductive fine particles by coating the electroconductive fine particle dispersion to a film thickness of the fine particle layer of 70 nm by die coating, and impregnating the binder dispersion onto the coated film of electroconductive fine particles to a film thickness after baking of 70 nm by die coating. Furthermore, the ratio of fine particles to binder in the transparent electroconductive film at this time was 10/8. Those results are shown in the following Table 4.

### Comparative Example 1

A multi-junction thin film silicon solar cell was produced and evaluated in the same manner as Example 1 with the exception of depositing ZnO supplemented with about 1×10²¹ cm⁻³ of gallium to a thickness of 80 nm under conditions of a substrate temperature of 150° C. using magnetron sputtering instead of coating the composition for a transparent electroconductive film of Example 1 onto the amorphous silicon layer 13. Those results are shown in the following Table 5.

### Comparative Example 2

A multi-junction thin film silicon solar cell was produced and evaluated in the same manner as Example 1 with the exception of depositing ZnO supplemented with about 1×10²¹ cm⁻³ of gallium to a thickness of 250 nm under conditions of a substrate temperature of 150° C. using magnetron sputtering in the same manner as Comparative Example 1 instead of coating the composition for transparent electroconductive film of Example 1 onto the amorphous silicon layer 13, followed by immersing this deposited substrate for 15 seconds in 0.5% by weight aqueous HCl solution held at liquid temperature of 15° C. and etching. Those results are shown in the following Table 5.

### Comparative Example 3

A multi-junction thin film silicon solar cell was produced in the same manner as Comparative Example 1 and evaluated in the same manner as Example 1 with the exception of depositing ZnO supplemented with about 1×10²¹ cm⁻³ of aluminum to a thickness of 50 nm under conditions of a substrate temperature of 150° C. using magnetron sputtering instead of the ZnO supplemented with gallium of Comparative Example 1. Those results are shown in the following Table 5.

### Comparative Example 4

A multi-junction thin film silicon solar cell was produced in the same manner as Comparative Example 2 and evaluated in the same manner as Example 1 with the exception of depositing ZnO supplemented with about 1×10²¹ cm⁻³ of aluminum to a thickness of 250 mm under conditions of a substrate temperature of 150° C. using magnetron sputtering instead of the ZnO supplemented with gallium of Comparative Example 2. Those results are shown in Table 5.

### Comparative Example 5

A multi-junction thin film silicon solar cell was produced in the same manner as Comparative Example 3 and evaluated in the same manner as Example 1 with the exception of depositing ZnO supplemented with about 1×10²¹ cm⁻³ of aluminum to a thickness of 30 nm. Those results are shown in the following Table 5.

Furthermore, although a silicon solar cell that uses silicon for the power generating layer was used in the aforementioned examples, the present invention is not limited to a silicon solar cell provided it is a multi-junction solar cell, but rather can also be applied to other types of solar cells such as CIG, CIGSS or CIS solar cells, CdTe or Cd solar cells, or organic thin film solar cells.

TABLE 1

| | Dispersion Containing | | | | | | | | | Film | Dispersion Containing | | | | | | |
|---|---|---|---|---|---|---|---|---|---|---|---|---|---|---|---|---|---|
| | Electroconductive Fine Particles | | | | | | | | | Thickness | Binder | | | | | Film | Fine |
| | | | | | | Dispersion | | | | of Fine | | | Dispersion | | | Thickness | Particle/Binder |
| | Fine Particles | | | Coupling Agent | | Medium | | Wt | | Particle | Binder | | Medium | | | After | Ratio |
| | | Particle | Parts by | | Parts by | | Parts by | ratio | Coating | Layer | | Parts by | | Parts by | Coating | Baking | After |
| | Type | Diameter | wt | Type | wt | Type | wt | (%) | method | (nm) | Type | wt | Type | wt | Method | (nm) | Baking |
| Ex. 1 | ITO | 0.03 | 1.0 | Ti-based | 0.01 | Ethanol | 98.99 | 99.01 | Spin | 80 | Siloxane | 1.0 | Ethanol | 99.0 | Spin | 90 | 1/1 |
| | (Sn/ | | | (3) | | | | | coating | | polymer | | | | coating | | |
| | (Sn + In) = 0.1 | | | | | | | | | | | | | | | | |
| Ex. 2 | ITO | 0.02 | 0.5 | Ti-based | 0.01 | Ethanol | 99.49 | 39.22 | Spin | 20 | Siloxane | 0.2 | Ethanol | 99.8 | Spin | 20 | 5/2 |
| | (Sn/ | | | (3) | | | | | coating | | polymer | | | | coating | | |
| | (Sn + In) = 0.05 | | | | | | | | | | | | | | | | |
| Ex. 3 | PTO (P/ | 0.02 | 1.0 | Ti-based | 0.02 | Ethanol | 98.98 | 98.04 | Spin | 70 | Siloxane | 1.0 | Ethanol | 99.0 | Spin | 70 | 1/1 |
| | (P + In) = 0.1 | | | (2) | | | | | coating | | polymer | | | | coating | | |
| Ex. 4 | ATO | 0.03 | 1.5 | Al-based | 0.02 | Ethanol | 98.48 | 78.95 | Spin | 120 | Siloxane | 1.2 | Ethanol | 98.8 | Spin | 120 | 15/12 |
| | (Sb/ | | | (1) | | | | | coating | | polymer | | | | coating | | |
| | (Sb + Sn) = 0.1 | | | | | | | | | | | | | | | | |
| Ex. 5 | InO | 0.03 | 1.2 | Vinyl tri- | 0.03 | Ethanol | 98.77 | 40.65 | Spin | 80 | Acrylic | 0.5 | Ethanol | 99.5 | Spin | 80 | 3/5 |
| | | | | ethoxy | | | | | coating | | resin | | | | coating | | |
| | | | | silane | | | | | | | | | | | | | |
| Ex. 6 | AZO | 0.03 | 0.8 | Ti-based | 0.01 | Ethanol | 99.19 | 98.77 | Spin | 60 | Cellulose | 0.8 | Butyl | 99.2 | Spin | 80 | 12/3 |
| | (Al/ | | | (4) | | | | | coating | | resin | | carbitol | | coating | | |
| | (Al + Zn) = 0.1 | | | | | | | | | | | | acetate | | | | |
| Ex. 7 | ITO | 0.02 | 1.5 | γ-glycidoxy | 0.01 | Ethanol | 98.49 | 59.60 | Spin | 100 | Epoxy | 0.9 | Toluene | 99.1 | Spin | 100 | 15/9 |
| | (Sn/ | | | propyl | | | | | coating | | resin | | | | coating | | |
| | (Sn + In) = 0.05 | | | trimethoxy | | | | | | | | | | | | | |
| | | | | silane | | | | | | | | | | | | | |
| Ex. 8 | ATO | 0.02 | 1.2 | Ti-based | 0.02 | Ethanol | 98.78 | 81.97 | Spin | 80 | Polyester | 1.0 | Xylene | 99.0 | Spin | 80 | 12/10 |
| | (Sb/ | | | (5) | | | | | coating | | resin | | | | coating | | |
| | (Sb + Sn) = 0.05 | | | | | | | | | | | | | | | | |
| Ex. 9 | PTO (P/ | 0.03 | 2.0 | γ-glycidoxy | 0.05 | Ethanol | 97.95 | 53.66 | Spin | 140 | Acryl- | 1.1 | Iso- | 98.9 | Spin | 140 | 20/11 |
| | (P + In) = 0.05 | | | propyl | | | | | coating | | urethane | | phorone | | coating | | |
| | | | | trimethoxy | | | | | | | resin | | | | | | |
| | | | | silane | | | | | | | | | | | | | |
| Ex. 10 | MgO | 0.03 | 0.8 | Ti-based | 0.02 | Ethanol | 99.18 | 121.95 | Spin | 70 | Poly- | 1.0 | Cyclo- | 99.0 | Spin | 100 | 8/10 |
| | | | | (4) | | | | | coating | | styrene | | hexanone | | coating | | |
| | | | | | | | | | | | resin | | | | | | |
| Ex. 11 | TiO₂ | 0.02 | 2.0 | Ti-based | 0.02 | Ethanol | 97.98 | 74.26 | Spin | 120 | Poly- | 1.5 | Toluene | 98.5 | Spin | 120 | 20/15 |
| | | | | (6) | | | | | coating | | vinyl | | | | coating | | |
| | | | | | | | | | | | acetate | | | | | | |
| | | | | | | | | | | | resin | | | | | | |
| Ex. 12 | Ag | 0.03 | 1.0 | Ti-based | 0.01 | Ethanol | 98.99 | 99.01 | Spin | 70 | Poly- | 1.0 | Ethanol | 99.0 | Spin | 80 | 1/1 |
| | | | | (7) | | | | | coating | | vinyl | | | | coating | | |
| | | | | | | | | | | | alcohol | | | | | | |
| | | | | | | | | | | | resin | | | | | | |
| Ex. 13 | Ag—Pd | 0.02 | 0.8 | Ti-based | 0.01 | Ethanol | 99.19 | 98.77 | Spin | 50 | Siloxane | 0.8 | Ethanol | 99.2 | Spin | 50 | 8/8 |
| | (Ag/Pd = 9/1) | | | (7) | | | | | coating | | polymer | | | | coating | | |
| Ex. 14 | Ag | 0.02 | 1.0 | Ti-based | 0.01 | Ethanol | 98.99 | 116.81 | Spin | 80 | Polyamide | 1.2 | Xylene | 98.8 | Spin | 110 | 10/12 |
| | | | | (8) | | | | | coating | | resin | | | | coating | | |
| Ex. 15 | Ru | 0.03 | 1.2 | Ti-based | 0.03 | Ethanol | 98.77 | 97.56 | Spin | 90 | Vinyl | 1.2 | Xylene | 98.8 | Spin | 100 | 12/12 |
| | | | | (9) | | | | | coating | | chloride | | | | coating | | |
| | | | | | | | | | | | resin | | | | | | |
| Ex. 16 | Rh | 0.03 | 1.0 | Ti-based | 0.02 | Ethanol | 98.98 | 78.43 | Spin | 80 | Acrylate | 0.8 | Ethanol | 99.2 | Spin | 80 | 10/8 |
| | | | | (8) | | | | | coating | | resin | | | | coating | | |
| Ex. 17 | ITO | 0.03 | 1.0 | Ti-based | 0.02 | Ethanol | 98.98 | 98.04 | Spin | 80 | Poly- | 1.0 | Toluene | 99.0 | Spin | 80 | 10/10 |
| | (Sn/ | | | (3) | | | | | coating | | carbonate | | | | coating | | |
| | (Sn + In) = 0.1 | | | | | | | | | | resin | | | | | | |

TABLE 2

| | Dispersion Containing Electroconductive | | | | | | | | | Film | Dispersion Containing | | | | | | |
|---|---|---|---|---|---|---|---|---|---|---|---|---|---|---|---|---|---|
| | Fine Particles | | | | | | | | | Thickness | Binder | | | | | Film | Fine |
| | | | | | | Dispersion | | | | of Fine | | | Dispersion | | | Thickness | Particle/Binder |
| | Fine Particles | | | Coupling Agent | | Medium | | Wt | | Particle | Binder | | Medium | | | After | Ratio |
| | | Particle | Parts by | | Parts by | | Parts by | ratio | Coating | Layer | | Parts by | | Parts by | Coating | Baking | After |
| | Type | Diameter | wt | Type | wt | Type | wt | (%) | Method | (nm) | Type | wt | Type | wt | Method | (nm) | Baking |
| Ex. 18 | PTO | 0.02 | 1.0 | Ti-based | 0.01 | Ethanol | 98.99 | 79.21 | Spin | 80 | Alkyd resin | 0.8 | Cyclo- | 99.2 | Spin | 100 | 10/8 |
| | (P/ | | | (3) | | | | | coating | | | | hexanone | | coating | | |
| | (P + In) = | | | | | | | | | | | | | | | | |
| | 0.1 | | | | | | | | | | | | | | | | |
| Ex. 19 | ATO | 0.03 | 1.0 | Ti-based | 0.02 | Ethanol | 98.98 | 117.65 | Spin | 80 | Poly- | 1.2 | Xylene | 98.8 | Spin | 80 | 10/12 |
| | (Sb/ | | | (3) | | | | | coating | | urethane | | | | coating | | |
| | (Sb + sn) = | | | | | | | | | | resin | | | | | | |
| | 0.1 | | | | | | | | | | | | | | | | |
| Ex. 20 | ITO | 0.02 | 1.0 | Ti-based | 0.01 | Ethanol | 98.99 | 79.21 | Spin | 80 | Polyacetal | 0.8 | Hexane | 99.2 | Spin | 90 | 10/8 |
| | (Sn/ | | | (2) | | | | | coating | | resin | | | | coating | | |
| | (Sn + In) = | | | | | | | | | | | | | | | | |
| | 0.05 | | | | | | | | | | | | | | | | |
| Ex. 21 | ATO | 0.03 | 1.0 | Ti-based | 0.02 | Ethanol | 98.98 | 98.04 | Spin | 80 | Ethyl | 1.0 | Hexane | 99.0 | Spin | 100 | 10/10 |
| | (Sb/ | | | (2) | | | | | coating | | cellulose | | | | coating | | |
| | (Sb + Sn) = | | | | | | | | | | resin | | | | | | |
| | 0.05 | | | | | | | | | | | | | | | | |
| Ex. 22 | PTO | 0.02 | 1.0 | Ti-based | 0.01 | Ethanol | 98.99 | 99.01 | Spin | 70 | Al | 1.0 | Methanol | 99.0 | Spin | 70 | 10/10 |
| | (P/ | | | (2) | | | | | coating | | Dethoxy- | | | | coating | | |
| | (P + In) = | | | | | | | | | | hydrolysate | | | | | | |
| | 0.05 | | | | | | | | | | | | | | | | |
| Ex. 23 | ATO | 0.02 | 1.0 | Ti-based | 0.02 | Ethanol | 98.98 | 98.04 | Spin | 70 | Alkyd | 1.0 | Iso- | 99.0 | Spin | 90 | 10/10 |
| | (Sb/ | | | (4) | | | | | coating | | resin/poly- | | phorone | | coating | | |
| | Sb + Sn) = | | | | | | | | | | amide | | | | | | |
| | 0.1 | | | | | | | | | | resin = 7/3 | | | | | | |
| Ex. 24 | Si | 0.02 | 1.0 | γ-glycidoxy | 0.01 | Ethanol | 98.99 | 99.01 | Spin | 80 | Siloxane | 1.0 | Ethanol | 99.0 | Spin | 80 | 10/10 |
| | | | | propyl | | | | | coating | | polymer | | | | coating | | |
| | | | | trimethoxy | | | | | | | | | | | | | |
| | | | | silane | | | | | | | | | | | | | |
| Ex. 25 | Ga | 0.03 | 1.0 | Ti-based | 0.01 | Ethanol | 98.99 | 99.01 | Spin | 80 | Alkyd | 1.0 | Cyclo- | 99.0 | Spin | 100 | 10/10 |
| | | | | (2) | | | | | coating | | resin | | hexanone | | coating | | |
| Ex. 26 | Co | 0.02 | 1.0 | Ti-based | 0.01 | Ethanol | 98.99 | 99.01 | Spin | 80 | Ethyl | 1.0 | Hexane | 99.0 | Spin | 80 | 10/10 |
| | | | | (2) | | | | | coating | | cellulose | | | | coating | | |
| | | | | | | | | | | | rein | | | | | | |
| Ex. 27 | Ca | 0.02 | 1.0 | Ti-based | 0.01 | Ethanol | 98.99 | 99.01 | Spin | 80 | Poly- | 1.0 | Toluene | 99.0 | Spin | 90 | 10/10 |
| | | | | (3) | | | | | coating | | carbonate | | | | coating | | |
| | | | | | | | | | | | resin | | | | | | |
| Ex. 28 | Sr | 0.03 | 1.0 | Ti-based | 0.01 | Ethanol | 98.99 | 99.01 | Spin | 80 | Polyacetal | 1.0 | Hexane | 99.0 | Spin | 100 | 10/10 |
| | | | | (3) | | | | | coating | | resin | | | | coating | | |
| Ex. 29 | Ba(OH)₂ | 0.02 | 1.0 | Ti-based | 0.01 | Ethanol | 98.99 | 99.01 | Spin | 80 | Poly- | 1.0 | Xylene | 99.0 | Spin | 80 | 10/10 |
| | | | | (4) | | | | | coating | | urethane | | | | coating | | |
| | | | | | | | | | | | rein | | | | | | |
| Ex. 30 | Ca | 0.03 | 1.0 | Ti-based | 0.01 | Ethanol | 98.99 | 99.01 | Spin | 80 | Polyamide | 1.0 | Xylene | 99.0 | Spin | 100 | 10/10 |
| | | | | (4) | | | | | coating | | rein | | | | coating | | |
| Ex. 31 | Y | 0.03 | 1.0 | Ti-based | 0.01 | Ethanol | 98.99 | 99.01 | Spin | 80 | Siloxane | 1.0 | Ethanol | 99.0 | Spin | 100 | 10/10 |
| | | | | (5) | | | | | coating | | polymer | | | | coating | | |
| Ex. 32 | Zr | 0.02 | 1.0 | Ti-based | 0.01 | Ethanol | 98.99 | 99.01 | Spin | 80 | Alkyd | 1.0 | Cyclo- | 99.0 | Spin | 80 | 10/10 |
| | | | | (5) | | | | | coating | | resin | | hexanone | | coating | | |
| Ex. 33 | Sn(OH)₂ | 0.02 | 1.0 | Ti-based | 0.01 | Ethanol | 98.99 | 99.01 | Spin | 80 | Ethyl | 1.0 | Hexane | 99.0 | Spin | 90 | 10/10 |
| | | | | (6) | | | | | coating | | cellulose | | | | coating | | |
| | | | | | | | | | | | resin | | | | | | |
| Ex. 34 | MgO/ | 0.03 | 1.0 | Ti-based | 0.01 | Ethanol | 98.99 | 99.01 | Spin | 80 | Poly- | 1.0 | Toluene | 99.0 | Spin | 80 | 10/10 |
| | ZnO₂ = | | | (6) | | | | | coating | | carbonate | | | | coating | | |
| | 5/5 | | | | | | | | | | resin | | | | | | |

TABLE 3

| | Dispersion Containing Electroconductive | | | | | | | | | Film | Dispersion Containing | | | | | | |
|---|---|---|---|---|---|---|---|---|---|---|---|---|---|---|---|---|---|
| | Fine Particles | | | | | | | | | Thickness | Binder | | | | | Film | Fine |
| | | | | Coupling | | Dispersion | | | | of Fine | | | Dispersion | | | Thickness | Particle/Binder |
| | Fine Particles | | | Agent | | Medium | | Wt | | Particle | Binder | | Medium | | | After | Ratio |
| | | Particle | Parts by | | Parts by | | Parts by | ratio | Coating | Layer | | Parts by | | Parts by | Coating | Baking | After |
| | Type | Diameter | wt | Type | wt | Type | wt | (%) | method | (nm) | Type | wt | Type | wt | Method | (nm) | Baking |
| Ex. 35 | c | 0.03 | 1.0 | Ti-based | 0.01 | Ethanol | 98.99 | 99.01 | Spin | 80 | Polyacetal | 1.0 | Hexane | 99.0 | Spin | 100 | 10/10 |
| | | | | (7) | | | | | coating | | rein | | | | coating | | |
| Ex. 36 | SiO₂ | 0.01 | 1.0 | Ti-based | 0.01 | Ethanol | 98.99 | 99.01 | Spin | 80 | Poly- | 1.0 | Xylene | 99.0 | Spin | 90 | 10/10 |
| | | | | (7) | | | | | coating | | urethane | | | | coating | | |
| | | | | | | | | | | | resin | | | | | | |
| Ex. 37 | Cu | 0.03 | 1.0 | Ti-based | 0.01 | Ethanol | 98.99 | 99.01 | Spin | 80 | Polyamide | 1.0 | xylene | 99.0 | Spin | 80 | 10/10 |
| | | | | (8) | | | | | coating | | resin | | | | coating | | |
| Ex. 38 | Ni | 0.03 | 1.0 | Ti-based | 0.01 | Ethanol | 98.99 | 99.01 | Spin | 80 | Siloxane | 1.0 | Ethanol | 99.0 | Spin | 80 | 10/10 |
| | | | | (8) | | | | | coating | | polymer | | | | coating | | |
| Ex. 39 | Pt | 0.02 | 1.0 | Al-based | 0.01 | Ethanol | 98.99 | 99.01 | Spin | 80 | Alkyd | 1.0 | Cyclo- | 99.0 | Spin | 100 | 10/10 |
| | | | | (1) | | | | | coating | | resin | | hexanone | | coating | | |
| Ex. 40 | Ir | 0.03 | 1.0 | Al-based | 0.01 | Ethanol | 98.99 | 99.01 | Spin | 80 | Ethyl | 1.0 | Hexane | 99.0 | Spin | 100 | 10/10 |
| | | | | (1) | | | | | coating | | cellulose | | | | coating | | |
| | | | | | | | | | | | resin | | | | | | |
| Ex. 41 | PTO (P/ | 0.02 | 0.8 | Al-based | 0.01 | Ethanol | 99.19 | 123.46 | Spin | 80 | Poly | 1.0 | Toluene | 99.0 | Spin | 80 | 8/10 |
| | (P + In) = | | | (1)/Ti- | | | | | coating | | carbonate | | | | coating | | |
| | 0.1 | | | based | | | | | | | resin | | | | | | |
| | | | | (3) = 5/5 | | | | | | | | | | | | | |
| Ex. 42 | ITO | 0.02 | 1.2 | Ti- | 0.02 | Ethanol | 98.78 | 81.97 | Spin | 100 | Siloxane | 1.0 | Ethanol | 99.0 | Spray | 120 | 12/10 |
| | (Sn/ | | | based | | | | | coating | | polymer | | | | coating | | |
| | (Sn + In) = | | | (3) | | | | | | | | | | | | | |
| | 0.1 | | | | | | | | | | | | | | | | |
| Ex. 43 | PTO (P/ | 0.03 | 1.2 | Ti- | 0.02 | Ethanol | 98.78 | 98.36 | Spin | 100 | Siloxane | 1.2 | Ethanol | 98.8 | Dispenser | 110 | 12/12 |
| | (P + In) = | | | based | | | | | coating | | polymer | | | | coating | | |
| | 0.1 | | | (3) | | | | | | | | | | | | | |
| Ex. 44 | ATO | 0.02 | 1.2 | Ti- | 0.02 | Ethanol | 98.78 | 65.57 | Spin | 100 | Siloxane | 0.8 | Ethanol | 99.2 | Knife | 100 | 12/8 |
| | (Sb/ | | | based | | | | | coating | | polymer | | | | coating | | |
| | (Sb + Sn) = | | | (3) | | | | | | | | | | | | | |
| | 0.1 | | | | | | | | | | | | | | | | |
| Ex. 45 | ITO | 0.02 | 1.2 | Ti- | 0.02 | Ethanol | 98.78 | 98.36 | Spin | 100 | Siloxane | 1.2 | Ethanol | 98.8 | Slit | 100 | 12/12 |
| | (Sn/ | | | based | | | | | coating | | polymer | | | | coating | | |
| | (Sn + In) = | | | (2) | | | | | | | | | | | | | |
| | 0.05 | | | | | | | | | | | | | | | | |
| Ex. 46 | ATO | 0.03 | 1.0 | Ti- | 0.01 | Ethanol | 98.99 | 99.01 | Spin | 90 | Siloxane | 1.0 | Ethanol | 99.0 | Inkjet | 90 | 10/10 |
| | (Sb/ | | | based | | | | | coating | | polymer | | | | coating | | |
| | (Sb + Sn) = | | | (2) | | | | | | | | | | | | | |
| | 0.05 | | | | | | | | | | | | | | | | |
| Ex. 47 | PTO (P/ | 0.02 | 5.0 | Ti-based | 0.05 | Ethylene | 94.95 | 99.01 | Gravure | 120 | Acrylic | 5.0 | Ethylene | 95.0 | Gravure | 120 | 50/50 |
| | (P + In) = | | | (2) | | glycol | | | printing | | rein | | glycol | | printing | | |
| | 0.05 | | | | | | | | | | | | | | | | |
| Ex. 48 | ATO | 0.02 | 5.0 | Ti- | 0.05 | Ethylene | 94.95 | 99.01 | Screen | 160 | Ethyl | 5.0 | Butyl | 95.0 | Screen | 170 | 50/50 |
| | (Sb/ | | | based | | glycol | | | printing | | cellulose | | carbitol | | printing | | |
| | (Sb + Sn) = | | | (4) | | | | | | | resin | | acetate | | | | |
| | 0.1 | | | | | | | | | | | | | | | | |
| Ex. 49 | PTO (P/ | 0.02 | 5.0 | — | — | Ethylene | 95.00 | 100.00 | Offset | 140 | Alkyd | 5.0 | Ethylene | 95.0 | Offset | 150 | 50/50 |
| | (P + In) = | | | | | glycol | | | printing | | resin | | glycol | | printing | | |
| | 0.1 | | | | | | | | | | | | | | | | |
| Ex. 50 | ATO | 0.02 | 1.0 | Ti- | 0.01 | Ethanol | 98.99 | 79.21 | Die | 70 | Siloxane | 0.8 | Ethanol | 99.2 | Die | 70 | 10/8 |
| | (Sb/ | | | based | | | | | coating | | polymer | | | | coating | | |
| | (Sb + Sn) = | | | (3) | | | | | | | | | | | | | |
| | 0.1 | | | | | | | | | | | | | | | | |

TABLE 4

| | | Short-circuit | |
|---|---|---|---|
| | | Current | Conversion |
| | | Density | efficiency |
| | Refractive | (relative | (relative |
| | Index (—) | value) | value) |
| Ex. 1 | 1.7 | 1.00 | 1.00 |
| Ex. 2 | 1.7 | 1.01 | 1.01 |
| Ex. 3 | 1.6 | 1.19 | 1.28 |
| Ex. 4 | 1.5 | 1.14 | 1.16 |
| Ex. 5 | 1.6 | 1.01 | 1.02 |
| Ex. 6 | 1.7 | 0.96 | 0.97 |
| Ex. 7 | 1.5 | 0.99 | 1.00 |
| Ex. 8 | 1.8 | 1.20 | 1.24 |
| Ex. 9 | 1.6 | 1.10 | 1.09 |
| Ex. 10 | 1.7 | 1.02 | 1.03 |
| Ex. 11 | 1.6 | 1.01 | 1.02 |
| Ex. 12 | 1.5 | 1.05 | 1.06 |
| Ex. 13 | 1.6 | 1.29 | 1.27 |
| Ex. 14 | 1.6 | 1.25 | 1.30 |
| Ex. 15 | 1.7 | 1.15 | 1.18 |
| Ex. 16 | 1.5 | 1.07 | 1.12 |
| Ex. 17 | 1.5 | 1.12 | 1.09 |
| Ex. 18 | 1.6 | 1.05 | 1.08 |
| Ex. 19 | 1.7 | 1.14 | 1.17 |
| Ex. 20 | 1.5 | 0.98 | 0.99 |
| Ex. 21 | 1.6 | 1.06 | 1.02 |
| Ex. 22 | 1.7 | 1.19 | 1.17 |
| Ex. 23 | 1.7 | 1.17 | 1.18 |
| Ex. 24 | 1.5 | 1.08 | 1.12 |
| Ex. 25 | 1.6 | 1.04 | 1.05 |
| Ex. 26 | 1.5 | 0.99 | 1.02 |
| Ex. 27 | 1.6 | 1.21 | 1.15 |
| Ex. 28 | 1.7 | 1.11 | 1.12 |
| Ex. 29 | 1.6 | 1.00 | 1.02 |
| Ex. 30 | 1.6 | 1.10 | 1.10 |
| Ex. 31 | 1.5 | 1.08 | 1.09 |
| Ex. 32 | 1.5 | 1.11 | 1.04 |
| Ex. 33 | 1.7 | 0.98 | 1.03 |
| Ex. 34 | 1.6 | 1.02 | 0.97 |
| Ex. 35 | 1.6 | 1.03 | 1.00 |
| Ex. 36 | 1.6 | 1.02 | 1.01 |
| Ex. 37 | 1.5 | 1.02 | 0.98 |
| Ex. 38 | 1.6 | 1.04 | 0.97 |
| Ex. 39 | 1.6 | 0.98 | 0.99 |
| Ex. 40 | 1.9 | 0.95 | 0.98 |
| Ex. 41 | 1.5 | 1.24 | 1.19 |
| Ex. 42 | 1.7 | 1.12 | 1.14 |
| Ex. 43 | 1.6 | 1.09 | 1.07 |
| Ex. 44 | 1.7 | 1.22 | 1.21 |
| Ex. 45 | 1.5 | 1.18 | 1.20 |
| Ex. 46 | 1.6 | 1.09 | 1.10 |
| Ex. 47 | 1.7 | 1.19 | 1.15 |
| Ex. 48 | 1.6 | 1.20 | 1.20 |
| Ex. 49 | 1.6 | 1.05 | 1.08 |
| Ex. 50 | 1.6 | 1.23 | 1.19 |

TABLE 5

| | Electro- | Refrac- | Short-circuit | |
|---|---|---|---|---|
| | conductive | tive | current | Conversion |
| | film | index | density | efficiency |
| | composition | (—) | (relative value) | (relative value) |
| Comp. Ex. 1 | ZnO + Ga | 2.1 | 0.85 | 0.87 |
| Comp. Ex. 2 | ZnO + Ga | 2.2 | 0.80 | 0.88 |
| Comp. Ex. 3 | ZnO + Al | 2.0 | 0.90 | 0.94 |
| Comp. Ex. 4 | ZnO + Al | 2.1 | 0.83 | 0.90 |
| Comp. Ex. 5 | ZnO + Al | 2.2 | 0.85 | 0.92 |

As is clear from Tables 4 and 5, Examples 1 to 50 demonstrate low refractive indices as well as high short-circuit current densities and conversion efficiencies, allowing the obtaining of superior cell performance in comparison with the transparent electroconductive films of Comparative Examples 1 to 5 in which ZnO films were formed by sputter deposition.

### Example 51

First, a square piece of glass measuring 10 cm on a side was prepared for the transparent substrate 11, and SnO₂ was used for the front side electrode layer 12. The film thickness of the front side electrode layer 12 at this time was 800 nm, the sheet resistance was 10 Ω/□, and the haze rate was 15 to 20%.

Next, the amorphous silicon layer 13 was deposited onto the front side electrode layer 12 at a thickness of 300 nm using plasma CVD.

Next, a composition for a transparent electroconductive film composed was prepared in the manner described below.

As shown in Table 1, 1.0 part by weight of ITO powder having en atomic ratio Sn/(Sn+In) of 0.1 and a particle diameter of 0.03 μm as electroconductive fine particles, 0.02 parts by weight of siloxane polymer obtained by hydrolyzing ethyl silicate as binder, and 0.01 part by weight of the organic titanate coupling agent represented by the aforementioned formula (3) as coupling agent were added followed by the addition of ethanol as dispersion medium to bring to a total of 100 parts by weight.

Furthermore, the average particle diameter of the electroconductive fine particles was measured by calculating from the number average as described below. First, electron micrographs of the target fine particles were taken. A SEM or TEM was suitably used for the electron microscope used for imaging according to the size of particle diameter and the type of powder. Next, the diameter of about 1000 of each particle was measured from the resulting electron micrographs to obtain frequency distribution data. A value of 50% for the cumulative frequency (D50) was used for the average particle diameter.

The fine particles in the mixture were dispersed by placing the mixture in a die mill (horizontal bead mill) and operating for 2 hours using zirconia beads having a diameter of 0.3 mm to obtain a composition for a transparent electroconductive film.

Continuing, the resulting composition for a transparent electroconductive film was coated onto the amorphous silicon layer 13 to a film thickness after baking of 80 nm by spin coating, followed by baking the coated film for 30 minutes at 200° C. to deposit the transparent electroconductive film 14. In addition, the film thickness after baking was measured from cross-sectional micrographs taken with an SEM. The ratio of fine particles to binder in the transparent electroconductive film obtained by baking was 10/2. Furthermore, the temperature during baking was conditioned on the average temperature being within ±5° of the set temperature as determined by measuring the temperatures at four locations on the square class plate measuring 10 cm on a side.

Continuing, the microcrystalline silicon layer 15 was deposited on the transparent electroconductive film 14 at a thickness of 1.7 μm using plasma CVD, and a ZnO film having a thickness of 80 nm and an Ag film having a thickness of 300 nm were respectively deposited as a back side electrode layer 16 by sputtering.

A multi-junction thin film silicon solar cell produced in this manner was then irradiated with light having an AM value of 1.5 as incident light at an optical luminosity of 100 mW/cm², followed by measuring the short-circuit current density and conversion efficiency of that time. Furthermore, the values for short-circuit current density and conversion efficiency of Example 51 were assigned a value of 1.0, and the values of short-circuit current density and conversion efficiency in the subsequent Examples 52 to 99 and Comparative Examples 6 to 10 were expressed as relative values based on the values of Example 51. In addition, refractive indices at a wavelength of 600 nm of the transparent electroconductive film 14 of the multi-junction thin film silicon solar cells were measured by preliminarily inputting film thicknesses observed in SEM cross-sections using a spectroscopic ellipsometer (M-2000D1, J. A. Woollam Japan) and analysis software “WVASE32” provided with the apparatus. Those results are shown in the following Table 9.

### EXAMPLE 52

As shown in Table 6, a multi-junction thin film silicon solar cell was produced and evaluated in the same manner as Example 51 with the exception of using a composition for a transparent electroconductive film obtained by adding 1.0 part by weight of ATO powder having an atomic ratio Sb/(Sb+Sn) of 0.1 and a particle diameter of 0.03 μm as electroconductive fine particles, adding 0.2 parts by weight of siloxane polymer as binder, and adding 0.01 part by weight of the aluminate coupling agent represented bf the aforementioned formula (1) as coupling agent followed by adding ethanol as dispersion medium to bring to a total of 100 parts by weight, and coating this composition for a transparent electroconductive film to a film thickness after baking of 90 nm by spin coating. Furthermore, the ratio of fine particles to binder in the transparent electroconductive film at this time was 10/2. Those results are shown in the following Table 9.

### EXAMPLE 53

As shown in Table 6, a multi-junction thin film silicon solar cell was produced and evaluated in the same manner as Example 51 with the exception of using a composition for a transparent electroconductive film obtained by adding 1.0 part by weight of PTO (P-doped SnO₂) powder having an atomic ratio P/(P+Sn) of 0.1 and a particle diameter of 0.02 μm as electroconductive fine particles, adding 0.2 parts by weight of siloxane polymer as binder, and adding 0.01 part by weight of the titanate coupling agent represented by the aforementioned formula (2) as coupling agent followed by adding ethanol as dispersion medium to bring to a total of 100 parts by weight, and coating this composition for a transparent electroconductive film to a film thickness after baking of 50 nm by spin coating. Furthermore, the ratio of fine particles to binder in the transparent electroconductive film at this time was 10/2. Those results are shown in the following Table 9.

### EXAMPLE 54

As shown in Table 6, a multi-junction thin film silicon solar cell was produced and evaluated in the same manner as Example 51 with the exception of using a composition for a transparent electroconductive film obtained by adding 1.0 part by weight of ZnO powder having a particle diameter of 0.03 μm as electroconductive fine particles, adding 0.2 parts by weight of acrylic resin as binder, and adding 0.01 part by weight of vinyltriethoxysilane as coupling agent followed by adding ethanol as dispersion medium to bring to a total of 100 parts by weight, and coating this composition for a transparent electroconductive film to a film thickness after baking of 60 nm by spin coating. Furthermore, the ratio of fine particles to binder in the transparent electroconductive film at this time was 10/2. Those results are shown in the following Table 9.

### EXAMPLE 55

As shown in Table 6, a multi-junction thin film silicon solar cell was produced and evaluated in the same manner as Example 51 with the exception of using a composition for a transparent electroconductive film obtained by adding 0.8 parts by weight of AZO powder having an atomic ratio Al/(Al+Zn) of 0.1 and a particle diameter of 0.03 μm as electroconductive fine particles, adding 0.2 parts by weight of cellulose resin as binder, and adding 0.01 part by weight of the titanate coupling agent represented by the aforementioned formula (4) as coupling agent followed by adding butyl carbitol acetate as dispersion medium to bring to a total of 100 parts by weight, and coating this composition for a transparent electroconductive film to a film thickness after baking of 30 nm by spin coating. Furthermore, the ratio of fine particles to binder in the transparent electroconductive film at this time was 8/2. Those results are shown in the following Table 9.

### EXAMPLE 56

As shown in Table 6, a multi-junction thin film silicon solar cell was produced and evaluated in the same manner as Example 51 with the exception of using a composition for a transparent electroconductive film obtained by adding 1.2 parts by weight of ITO powder having an atomic ratio Sn/(Sn+In) of 0.05 and a particle diameter of 0.02 μm as electroconductive fine particles, adding 0.3 parts by weight of epoxy resin as binder, and adding 0.02 parts by weight of γ-methacryloxypropyltrimethoxysilane as coupling agent followed by adding toluene as dispersion medium to bring to a total of 100 parts by weight, and coating this composition for a transparent electroconductive film to a film thickness after baking of 70 nm by spin coating. Furthermore, the ratio of fine particles to binder in the transparent electroconductive film at this time was 12/3. Those results are shown in the following Table 9.

### EXAMPLE 50

As shown in Table 6, a multi-junction thin film silicon solar cell was produced and evaluated in the same manner as Example 51 with the exception of using a composition for a transparent electroconductive film obtained by adding 1.0 part by weight of ATO powder having an atomic ratio Sb/(Sb+Sn) of 0.05 and a particle diameter of 0.02 μm as electroconductive fine particles, adding 0.5 parts by weight of polyester resin as binder, and adding 0.03 parts by weight of the titanate coupling agent represented by the aforementioned formula (5) as coupling agent followed by adding xylene as dispersion medium to bring to a total of 100 parts by weight, and coating this composition for a transparent electroconductive film to a film thickness after baking of 50 nm by spin coating. Furthermore, the ratio of fine particles to binder in the transparent electroconductive film at this time was 10/5. Those results are shown in the following Table 9.

### EXAMPLE 58

As shown in Table 6, a multi-junction thin film silicon solar cell was produced and evaluated in the same manner as Example 51 with the exception of using a composition for a transparent electroconductive film obtained by adding 1.2 parts by weight of PTO powder having an atomic ratio P/(P+Sn) of 0.05 and a particle diameter of 0.03 μm as electroconductive fine particles, adding 0.8 parts by weight of acrylurethane resin as binder, and adding 0.01 part by weight of γ-glycidoxypropyltrimethoxysilane as coupling agent followed by adding isophorone as dispersion medium to bring to a total of 100 parts by weight. Furthermore, the ratio of fine particles to binder in the transparent electroconductive film at this time was 12/8. Those results are shown in the following Table 9.

### EXAMPLE 59

As shown in Table 6, a multi-junction thin film silicon solar cell was produced and evaluated in the same manner as Example 51 with the exception of using a composition for a transparent electroconductive film obtained by adding 0.8 parts by weight of MgO powder having a particle diameter of 0.03 μm as electroconductive fine particles, adding 0.6 parts by weight of polystyrene resin as binder, and adding 0.02 parts by weight of the titanate coupling agent represented by the aforementioned formula (4) as coupling agent followed by adding cyclohexanone as dispersion medium to bring to a total of 100 parts by weight, and coating this composition for a transparent electroconductive film to a film thickness after baking of 70 nm by spin coating. Furthermore, the ratio of fine particles to binder in the transparent electroconductive film at this time was 8/6. Those results are shown in the following Table 9.

### EXAMPLE 60

As shown in Table 6, a multi-junction thin film silicon solar cell was produced and evaluated in the same manner as Example 51 with the exception of using a composition for a transparent electroconductive film obtained by adding 1.0 part by weight of TiO₂ powder having a particle diameter of 0.02 μm as electroconductive fine particles, adding 0.5 parts by weight of polyvinyl acetate resin as binder, and adding 0.03 parts by weight of the titanate coupling agent represented by the aforementioned formula (6) as coupling agent followed by adding toluene as dispersion medium to bring to a total of 100 parts by weight, and coating this composition for a transparent electroconductive film to a film thickness after baking of 70 nm by spin coating. Furthermore, the ratio of fine particles to binder in the transparent electroconductive film at this time was 10/5. Those results are shown in the following Table 9.

### EXAMPLE 61

As shown in Table 6, a multi-junction thin film silicon solar cell was produced and evaluated in the same manner as Example 51 with the exception of using a composition for a transparent electroconductive film obtained by adding 0.8 parts by weight of Ag powder having a particle diameter 0.03 μm as electroconductive fine particles, adding 0.8 parts by weight of polyvinyl alcohol resin as binder, and adding 0.01 part by weight of the titanate coupling agent represented by the aforementioned formula (7) as coupling agent followed by adding ethanol as dispersion medium to bring to a total of 100 parts by weight, and coating this composition for a transparent electroconductive film to a film thickness after baking of 50 nm by spin coating. Furthermore, the ratio of fine particles to binder in the transparent electroconductive film at this time was 8/8. Those results are shown in the following Table 9.

### EXAMPLE 62

As shown in Table 6, multi-junction thin film silicon solar cell was produced and evaluated in the same manner as Example 51 with the exception of using a composition for a transparent electroconductive film obtained by adding 0.5 parts by weight of Ag—Pd alloy powder having a ratio of Ag/Pd of 9/1 and a particle diameter of 0.02 μm as electroconductive fine particles, adding 0.7 parts by weight of siloxane polymer as binder, and adding 0.02 parts by weight of the titanate coupling agent represented by the aforementioned formula (7) as coupling agent followed by adding ethanol as dispersion medium to bring to a total of 100 parts by weight, and coating this composition for a transparent electroconductive film to a film thickness after baking of 50 nm by spin coating. Furthermore, the ratio of fine particles to binder in the transparent electroconductive film at this time was 5/7. Those results are shown in the following Table 9.

### EXAMPLE 63

As shown in Table 6, a multi-junction thin film silicon solar cell was produced and evaluated in the same manner as Example 51 with the exception of using a composition for a transparent electroconductive film obtained by adding 1.0 part by weight of Au powder having a particle diameter of 0.03 μm as electroconductive fine particles, adding 0.8 parts by weight of polyamide resin as binder, and adding 0.01 part by weight of the titanate coupling agent represented by the aforementioned formula (8) as coupling agent followed by adding xylene as dispersion medium to bring to a total of 100 parts by weight. Furthermore, the ratio of fine particles to binder in the transparent electroconductive film at this time was 10/8. Those results are shown in the following Table 9.

### EXAMPLE 64

As shown in Table 6, a multi-junction thin film silicon solar cell was produced and evaluated in the same manner as Example 51 with the exception of using a composition for a transparent electroconductive film obtained by adding 0.8 parts by weight of Ru powder having a particle diameter of 0.03 μm as electroconductive fine particles, adding 1.0 part by weight of vinyl chloride resin as binder, and adding 0.02 parts by weight of the titanate coupling agent represented by the aforementioned formula (8) as coupling agent followed by adding xylene as dispersion medium to bring to a total of 100 parts by weight. Furthermore, the ratio of fine particles to binder in the transparent electroconductive film at this time was 8/10. Those results are shown in the following Table 9.

### EXAMPLE 65

As shown in Table 6, a multi-junction thin film silicon solar cell was produced and evaluated in the same manner as Example 51 with the exception of using a composition for a transparent electroconductive film obtained by adding 1.2 parts by weight of Rh powder having a particle diameter of 0.03 μm as electroconductive fine particles, adding 1.0 part by weight of acrylate resin as binder, and adding 0.02 parts by weight of the titanate coupling agent represented by the aforementioned formula (8) as coupling agent followed by adding ethanol as dispersion medium to bring to a total of 100 parts by weight, and coating this composition for a transparent electroconductive film to a film thickness after baking of 70 nm by spin coating. Furthermore, the ratio of fine particles to binder in the transparent electroconductive film at this time was 12/10. Those results are shown in the following Table 9.

### EXAMPLE 66

As shown in Table 6, a multi-junction thin film silicon solar cell was produced and evaluated in the same manner as Example 51 with the exception of using a composition for a transparent electroconductive film obtained by adding 1.0 part by weight of ITO powder having an atomic ratio Sn/(Sn+In) of 0.1 and a particle diameter of 0.03 μm as electroconductive fine particles, adding 0.2 parts by weight of polycarbonate resin as binder, and adding 0.01 part by weight of the titanate coupling agent represented by the aforementioned formula (3) as coupling agent followed by adding toluene as dispersion medium to bring to a total of 100 parts by weight. Furthermore, the ratio of fines particles to binder in the transparent electroconductive film at this time was 10/2. Those results are shown in the following Table 9.

### EXAMPLE 67

As shown in Table 6, a multi-junction thin film silicon solar cell was produced and evaluated in the same manner as Example 51 with the exception of using a composition for a transparent electroconductive film obtained by adding 1.0 part by weight of PTO (P-doped SnO₂) powder having as atomic ratio P/(P+Sn) of 0.1 and a particle diameter of 0.02 μm as electroconductive fine particles, adding 0.2 parts by weight of alkyd resin as binder, and adding 0.01 part by weight of the titanate coupling agent represented by the aforementioned formula (3) as coupling agent followed by adding cyclohexanone as dispersion medium to bring to a total of 100 parts by weight, and coating this composition for a transparent electroconductive film to a film thickness after baking of 90 nm by spin coating. Furthermore, the ratio of fine particles to binder in the transparent electroconductive film at this time was 10/2. Those results are shown in the following Table 9.

### EXAMPLE 68

As shown in Table 7, a multi-junction thin film silicon solar cell was produced and evaluated in the same manner as Example 51 with the exception of a using a composition for a transparent electroconductive film obtained by adding 1.0 part by weight of ATO powder having an atomic ratio Sb/(Sb+Sn) of 0.1 and a particle diameter of 0.03 μm as electroconductive fine particles, adding 0.2 parts by weight of polyurethane resin as binder, and adding 0.01 part by weight of the titanate coupling agent represented by the aforementioned formula (3) as coupling agent followed by adding xylene as dispersion medium to bring to a total of 100 parts by weight, and coating this composition for a transparent electroconductive film to a film thickness after baking of 70 nm by spin coating. Furthermore, the ratio of fine particles to binder in the transparent electroconductive film at this time was 10/2. Those results are shown in the following Table 9.

### EXAMPLE 69

As shown in Table 7, a multi-junction thin film silicon solar cell was produced and evaluated in the same manner as Example 51 with the exception of using a composition for a transparent electroconductive film obtained by adding 1.0 part by weight of ITO powder having an atomic ratio Sn/(Sn+In) of 0.05 and a particle diameter of 0.02 μm as electroconductive fine particles, adding 0.2 parts by weight of polyacetal resin as binder, and adding 0.01 part by weight of the titanate coupling agent represented by the aforementioned formula (2) as coupling agent followed by adding hexane as dispersion medium to bring to a total of 100 parts by weight. Furthermore, the ratio of fine particles to binder in the transparent electroconductive film at this time was 10/2. Those results are shown in the following Table 9.

### EXAMPLE 70

As shown in Table 7, a multi-junction thin film silicon solar cell was produced and evaluated in the same manner as Example 51 with the exception of using a composition for a transparent electroconductive film obtained by adding 1.0 part by weight of ATO powder having an atomic ratio Sb/(Sb+Sn) of 0.05 and a particle diameter of 0.03 μm as electroconductive fine particles, adding 0.2 parts by weight of ethyl cellulose resin as binder, and adding 0.01 part by weight of the titanate coupling agent represented by the aforementioned formula (2) as coupling agent followed by adding hexane as dispersion medium to bring to a total of 100 parts by weight. Furthermore, the ratio of fine particles to binder in the transparent electroconductive film at this time was 10/2. Those results are shown in the following Table 9.

### EXAMPLE 71

As shown in Table 7, a multi-junction thin film silicon solar cell was produced and evaluated in the same manner as Example 51 with the exception of using a composition for a transparent electroconductive film obtained by adding 1.0 part by weight of PTO (P-doped SnO₂) powder having an atomic ratio P/(P+Sn) of 0.05 and a particle diameter of 0.02 μm as electroconductive fine particles, adding 0.2 parts by weight of Al methoxyhydrolysate as binder, and adding 0.01 part by weight of the titanate coupling agent represented by the aforementioned formula (2) as coupling agent followed by adding methanol as dispersion medium to bring to a total of 100 parts by weight, and coating this composition for a transparent electroconductive film to a film thickness after baking of 70 nm by spin coating. Furthermore, the ratio of fine particles to binder in the transparent electroconductive film at this time was 10/2. Those results are shown in the following Table 9.

### EXAMPLE 72

As shown in Table 7, a multi-junction thin film silicon solar cell was produced and evaluated in the same manner as Example 51 with the exception of using a composition for a transparent electroconductive film obtained by adding 1.0 part by weight of ATO powder having an atomic ratio Sb/(Sb+Sn) of 0.1 and a particle diameter of 0.02 μm as electroconductive fine particles, adding 0.2 parts by weight of a 7:3 mixture of alkyd resin and polyamide resin as binder, and adding 0.01 part by weight of the titanate coupling agent represented by the aforementioned formula (4) as coupling agent followed by adding isophorone as dispersion medium to bring to a total of 100 parts by weight, and coating this composition for a transparent electroconductive film to a film thickness after baking of 70 nm by spin coating. Furthermore, the ratio of fine particles to binder in the transparent electroconductive film at this time was 10/2. Those results are shown in the following Table 9.

### EXAMPLE 73

As shown in Table 7, a multi-junction thin film silicon solar cell was produced and evaluated in the same manner as Example 51 with the exception of using a composition for a transparent electroconductive film obtained by adding 1.0 part by weight of Si powder having a particle diameter of 0.02 μm as electroconductive fine particles, adding 0.2 parts by weight of siloxane polymer as binder, and adding 0.01 part by weight of γ-methacryloxypropyltrimethoxysilane as coupling agent followed by adding ethanol as dispersion medium to bring to a total of 100 parts by weight. Furthermore, the ratio of fine particles to binder in the transparent electroconductive film at this time was 10/2. Those results are shown in the following Table 9.

### EXAMPLE 74

As shown in Table 7, a multi-junction thin film silicon solar cell was produced and evaluated in the same manner as Example 51 with the exception of using a composition for a transparent electroconductive film obtained by adding 1.0 part by weight of Ga powder having a particle diameter of 0.03 μm as electroconductive fine particles, adding 0.2 parts by weight of alkyd resin as binder, and adding 0.01 part by weight of the titanate coupling agent represented by the aforementioned formula (2) as coupling agent followed by adding cyclohexanone as dispersion medium to bring to a total of 100 parts by weight. Furthermore, the ratio of fine particles to binder in the transparent electroconductive film at this time was 10/2. Those results are shown in the following Table 9.

### EXAMPLE 75

As shown in Table 7, a multi-junction thin film silicon solar cell was produced and evaluated in the same manner as Example 51 with the exception of using a composition for a transparent electroconductive film obtained by adding 1.0 part by weight of Co powder having a particle diameter of 0.02 μm as electroconductive fine particles, adding 0.2 parts by weight of ethyl cellulose resin as binder, and adding 0.01 part by weight of the titanate coupling agent represented by the aforementioned formula (2) as coupling agent followed by adding hexane as dispersion medium to bring to a total of 100 parts by weight, and coating this composition for a transparent electroconductive film to a film thickness after baking of 70 nm by spin coating. Furthermore, the ratio of fine particles to binder in the transparent electroconductive film at this time was 10/2. Those results are shown in the following Table 9.

### EXAMPLE 76

As shown in Table 7, a multi-junction thin film silicon solar cell was produced and evaluated in the same manner as Example 51 with the exception of using a composition for a transparent electroconductive film obtained by adding 1.0 part by weight of Ca powder having a particle diameter of 0.02 μm as electroconductive fine particles, adding 0.2 parts by weight of polycarbonate resin as binder, and adding 0.01 part by weight of the titanate coupling agent represented by the aforementioned formula (3) as coupling agent followed by adding toluene as dispersion medium to bring to a total of 100 parts by weight, and coating this composition for a transparent electroconductive film to a film thickness after baking of 70 nm by spin coating. Furthermore, the ratio of fine particles to binder in the transparent electroconductive film at this time was 10/2. Those results are shown in the following Table 9.

### EXAMPLE 77

As shown in Table 7, a multi-junction thin film silicon solar cell was produced and evaluated in the same manner as Example 51 with the exception of using a composition for a transparent electroconductive film obtained by adding 1.0 part by weight of Sr powder having a particle diameter of 0.03 μm as electroconductive fine particles, adding 0.2 parts by weight of polyacetal resin as binder, and adding 0.01 part by weight of the titanate coupling agent represented by the aforementioned formula (3) as coupling agent followed by adding hexane as dispersion medium to bring to a total of 100 parts by weight. Furthermore, the ratio of fine particles to binder in the transparent electroconductive film at this time was 10/2. Those results are shown in the following Table 9.

### EXAMPLE 78

As shown in Table 7, a multi-junction thin film silicon solar cell was produced and evaluated in the same manner as Example 51 with the exception of using a composition for a transparent electroconductive film obtained by adding 1.0 part by weight of Ba (OH)₂ powder hawing a particle diameter of 0.02 μm as electroconductive fine particles, adding 0.2 parts by weight of polyurethane resin as binder, and adding 0.01 part by weight of the titanate coupling agent represented by the aforementioned formula (4) as coupling agent followed by adding xylene as dispersion medium to bring to a total of 100 parte by weight. Furthermore, the ratio of fine particles to binder in the transparent electroconductive film at this time was 10/2. Those results are shown in the following Table 9.

### EXAMPLE 79

As shown in Table 7, a multi-junction thin film silicon solar cell was produced and evaluated in the same manner as Example 51 with the exception of using a composition for a transparent electroconductive film obtained by adding 1.0 part by weight of Ce powder having a particle diameter of 0.03 μm as electroconductive fine particles, adding 0.2 parts by weight of polyamide resin as binder, and adding 0.01 part by weight of the titanate coupling agent represented by the aforementioned formula (4) as coupling agent followed by adding xylene as dispersion medium to bring to a total of 100 parts by weight, and coating this composition for a transparent electroconductive film to a film thickness after baking of 70 nm by spin coating. Furthermore, the ratio of fine particles to binder in the transparent electroconductive film at this time was 10/2. Those results are shown in the following Table 9.

### EXAMPLE 80

As shown in Table 7, a multi-junction thin film silicon solar cell was produced and evaluated in the same manner as Example 51 with the exception of using a composition for a transparent electroconductive film obtained by adding 1.0 part by weight of Y powder having a particle diameter of 0.03 μm as electroconductive fine particles, adding 0.2 parts by weight of siloxane polymer as binder, and adding 0.01 part by weight of the titanate coupling agent represented by the aforementioned formula (5) as coupling agent followed by adding ethanol as dispersion medium to bring to a total of 100 parts by weight, and coating this composition for a transparent electroconductive film to a film thickness after baking of 70 nm by spin coating. Furthermore, the ratio of fine particles to binder in the transparent electroconductive film at this time was 10/2. Those results are shown in the following Table 9.

### EXAMPLE 81

As shown in Table 7, a multi-junction thin film silicon solar cell was produced and evaluated in the same manner as Example 51 with the exception of using a composition for a transparent electroconductive film obtained by adding 1.0 part by weight of Zr powder baring a particle diameter of 0.02 μm as electroconductive fine particles, adding 0.2 parts by weight of alkyd resin as binder, and adding 0.01 part by weight of the titanate coupling agent represented by the aforementioned formula (5) as coupling agent followed by adding cyclohexanone as dispersion medium to bring to a total of 100 parts by weight. Furthermore, the ratio of fine particles to binder in the transparent electroconductive film at this time was 10/2. Those results are shown in the following Table 9.

### EXAMPLE 82

As shown in Table 7, a multi-junction thin film silicon solar cell was produced and evaluated in the same manner as Example 51 with the exception of using a composition for a transparent electroconductive film obtained by adding 1.0 part by weight of Sn(OH)₂ powder having a particle diameter of 0.02 μm as electroconductive fine particles, adding 0.2 parts by weight of ethyl cellulose resin as binder, and adding 0.01 part by weight of the titanate coupling agent represented by the aforementioned formula (6) as coupling agent followed by adding hexane as dispersion medium to bring to a total of 100 parts by weight. Furthermore, the ratio of fine particles to binder in the transparent electroconductive film at this time was 10/2. Those results are shown in the following Table 9.

### EXAMPLE 83

As shown in Table 7, a multi-junction thin film silicon solar cell was produced and evaluated in the same manner as Example 51 with the exception of using a composition for a transparent electroconductive film obtained by adding 1.0 part by weight of a 5:5 ratio of MgO and ZnO₂ powder having a particle diameter of 0.03 μm as electroconductive fine particles, adding 0.2 parts by weight of polycarbonate resin as binder, and adding 0.01 part by weight of the titanate coupling agent represented by the aforementioned formula (6) as coupling agent followed by adding toluene as dispersion medium to bring to a total of 100 parts by weight. Furthermore, the ratio of fine particles to binder in the transparent electroconductive film at this time was 10/2. Those results are shown in the following Table 9.

### EXAMPLE 84

As shown in Table 7, a multi-junction thin film silicon solar cell was produced and evaluated in the same manner as Example 51 with the exception of using a composition for a transparent electroconductive film obtained by adding 1.0 part by weight of C powder having a particle diameter of 0.03 μm as electroconductive fine particles, adding 0.2 parts by weight of polyacetal resin as binder, and adding 0.01 part by weight of the titanate coupling agent represented by the aforementioned formula (7) as coupling agent followed by adding hexane as dispersion medium to bring to a total of 100 parts by weight. Furthermore, the ratio of fine particles to binder in the transparent electroconductive film at this time was 10/2. Those results are shown in the following Table 9.

### EXAMPLE 85

As shown in Table 8, a multi-junction thin film silicon solar cell was produced and evaluated in the same manner as Example 51 with the exception of using a composition for a transparent electroconductive film obtained by adding 1.0 part by weight of SiO₂ powder having a particle diameter of 0.01 μm as electroconductive fine particles, adding 0.2 parts by weight of polyurethane resin as binder, and adding 0.01 part by weight of the titanate coupling agent represented by the aforementioned formula (7) as coupling agent followed by adding xylene as dispersion medium to bring to a total of 100 parts by weight. Furthermore, the ratio of fine particles to binder in the transparent electroconductive film at this time was 10/2. Those, results are shown in the following Table 9.

### EXAMPLE 86

As shown in Table 8, a multi-junction thin film silicon solar cell was produced and evaluated in the same manner as Example 51 with the exception of using a composition for a transparent electroconductive film obtained by adding 1.0 part by weight of Cu powder having a particle diameter of 0.03 μm as electroconductive fine particles, adding 0.2 parts by weight of polyamide resin as binder, and adding 0.01 part by weight of the titanate coupling agent represented by the aforementioned formula (8) as coupling agent followed by adding xylene as dispersion medium to bring to a total of 100 parts by weight. Furthermore, the ratio of fine particles to binder in the transparent electroconductive film at this time was 10/2. These results are shown in the following Table 9.

### EXAMPLE 87

As shown in Table 8, a multi-junction thin film silicon solar cell was produced and evaluated in the same manner as Example 51 with the exception of using a composition for a transparent electroconductive film obtained by adding 1.0 part by weight of Ni powder having a particle diameter of 0.03 μm as electroconductive fine particles, adding 0.2 parts by weight of siloxane polymer as binder, and adding 0.01 part by weight of the titanate coupling agent represented by the aforementioned formula (8) as coupling agent followed by adding ethanol as dispersion medium to bring to a total of 100 parts by weight. Furthermore, the ratio of fine particles to binder in the transparent electroconductive film at this time was 10/2. Those results are shown in the following Table 9.

### EXAMPLE 88

As shown in Table 8, a multi-junction thin film silicon solar cell was produced and evaluated in the same manner as Example 51 with the exception of using a composition for a transparent electroconductive film obtained by adding 1.0 part by weight of Pt powder having a particle diameter of 0.02 μm as electroconductive fine particles, adding 0.2 parts by weight of alkyd resin as binder, and adding 0.01 part by weight of the aluminate coupling agent represented by the aforementioned formula (1) as coupling agent followed by adding cyclohexanone as dispersion medium to bring to a total of 100 parts by weight. Furthermore, the ratio of fine particles to binder in the transparent electroconductive film at this time was 10/2. Those results are shown in the following Table 9.

### EXAMPLE 89

As shown in Table 8, a multi-junction thin film silicon solar cell was produced and evaluated in the same manner as Example 51 with the exception of using a composition for a transparent electroconductive film obtained by adding 1.0 part by weight of Ir powder having a particle diameter of 0.03 μm as electroconductive fine particles, adding 0.2 parts by weight of ethyl cellulose resin as binder, and adding 0.01 part by weight of the aluminate coupling agent represented by the aforementioned formula (1) as coupling agent followed by adding hexane as dispersion medium to bring to a total of 100 parts by weight, and coating this composition for a transparent electroconductive film to a film thickness after baking of 70 nm by spin coating. Furthermore, the ratio of fine particles to binder in the transparent electroconductive film at this time was 10/2. Those results are shown in the following Table 9.

### EXAMPLE 90

As shown in Table 8, a multi-junction thin film silicon solar cell was produced and evaluated in the same manner as Example 51 with the exception of using a composition for a transparent electroconductive film obtained by adding 1.4 parts by weight of PTO (P-doped SnO₂) powder having an atomic ratio P/(P+Sn) of 0.1 and a particle diameter of 0.02 μm as electroconductive fine particles, adding 0.6 parts by weight of polycarbonate resin as binder, and adding 0.04 parts by weight of a 5:5 mixture of the aluminate coupling agent represented by the aforementioned formula (1) and the titanate coupling agent represented by the aforementioned formula (3) as coupling agent followed by adding toluene as dispersion medium to bring to a total of 100 parts by weight, and coating this composition for a transparent electroconductive film to a film thickness after baking of 110 nm by spin coating. Furthermore, the ratio of fine particles to binder in the transparent electroconductive film at this time was 14/6. Those results are shown in the following Table 9.

### EXAMPLE 91

As shown in Table 8, a multi-junction thin film silicon solar cell was produced and evaluated in the same manner as Example 51 with the exception of using a composition for a transparent electroconductive film obtained by adding 1.2 parts by weight of ITO powder having an atomic ratio Sn/(Sn+In) of 0.1 and a particle diameter of 0.02 μm as electroconductive fine particles, adding 0.3 parts by weight of siloxane polymer as binder, and adding 0.02 parts by weight of the titanate coupling agent represented by the aforementioned formula (3) as coupling agent followed by adding ethanol as dispersion medium to bring to a total of 100 parts by weight, and coating this composition for a transparent electroconductive film to a film thickness after baking of 100 nm by spray coating. Furthermore, the ratio of fine particles to binder in the transparent electroconductive film at this time was 12/3. Those results are shown in the following Table 9.

### EXAMPLE 92

As shown in Table 8, a multi-junction thin film silicon solar cell was produced and evaluated in the same manner as Example 51 with the exception of using a composition for a transparent electroconductive film obtained by adding 1.2 parts by weight of PTO (P-doped SnO₂) powder having an atomic ratio P/(P+Sn) of 0.1 and a particle diameter of 0.03 μm as electroconductive fine particles, adding 0.3 parts by weight of siloxane polymer as binder, and adding 0.02 parts by weight of the titanate coupling agent represented by the aforementioned formula (3) as coupling agent followed by adding ethanol as dispersion medium to bring to a total of 100 parts by weight, and coating this composition for a transparent electroconductive film to a film thickness after baking of 100 nm by dispenser coating. Furthermore, the ratio of fine particles to binder in the transparent electroconductive film at this time was 12/3. Those results are shown in the following Table 9.

### EXAMPLE 93

As shown in Table 8, a multi-junction thin film silicon solar cell was produced and evaluated in the same manner as Example 51 with the exception of using a composition for a transparent electroconductive film obtained by adding 1.0 part by weight of ATO powder having an atomic ratio Sb/(Sb+Sn) of 0.1 and a particle diameter of 0.02 μm as electroconductive fine particles, adding 0.3 parts by weight of siloxane polymer as binder, and adding 0.01 part by weight of the titanate coupling agent represented by the aforementioned formula (3) as coupling agent followed by adding ethanol as dispersion medium to bring to a total of 100 parts by weight, and coating this composition for a transparent electroconductive film to a film thickness after baking of 80 nm by knife coating. Furthermore, the ratio of fine particles to binder in the transparent electroconductive film at this time was 10/3. Those results are shown in the following Table 9.

### EXAMPLE 94

As shown in Table 8, a multi-function thin film silicon solar cell was produced and evaluated in the same manner as Example 51 with the exception of using a composition for a transparent electroconductive film obtained by adding 1.0 part by weight of ITO powder having an atomic ratio Sn/(Sn+In) of 0.05 and a particle diameter of 0.02 μm as electroconductive fine particles, adding 0.3 parts by weight of siloxane polymer as binder, and adding 0.01 part by weight of the titanate coupling agent represented by the aforementioned formula (2) as coupling agent followed by adding ethanol as dispersion medium to bring to a total of 100 parts by weight, and coating this composition for a transparent electroconductive film to a film thickness after baking of 80 as by slit coating. Furthermore, the ratio of fine particles to binder in the transparent electroconductive film at this time was 10/3. Those results are shown in the following Table 9.

### EXAMPLE 95

As shown in Table 8, a multi-junction thin film silicon solar cell was produced and evaluated in the same manner as Example 51 with the exception of using a composition for a transparent electroconductive film obtained by adding 1.0 part by weight of ATO powder having an atomic ratio Sb/(Sb+Sn) of 0.05 and a particle diameter of 0.03 μm as electroconductive fine particles, adding 0.3 parts by weight of siloxane polymer is binder, and adding 0.01 part by weight of the titanate coupling agent represented by the aforementioned formula (2) as coupling agent followed by adding ethanol as dispersion medium to bring to a total of 100 parts by weight, and coating this composition for a transparent electroconductive film to a film thickness after baking of 80 nm by inkjet coating. Furthermore, the ratio of fine particles to binder in the transparent electroconductive film at this time 10/3. Those results are shown in the following Table 9.

### EXAMPLE 96

As shown in Table 8, a multi-junction thin film silicon solar cell was produced and evaluated in the same manner as Example 51 with the exception of using a composition for a transparent electroconductive film obtained by adding 5.0 parts by weight, of PTO (P-doped SnO₂) powder having an atomic ratio P/(P+Sn) of 0.05 and a particle diameter of 0.02 μm as electroconductive fine particles, adding 5.0 parts by weight of acrylic resin as binder, and adding 0.05 parts by weight of the titanate coupling agent represented by the aforementioned formula (2) as coupling agent followed by adding ethylene glycol as dispersion medium to bring to a total of 100 parts by weight, and coating this composition for a transparent electroconductive film to a film thickness after baking of 120 nm by gravure printing. Furthermore, the ratio of fine particles to binder in the transparent electroconductive film at this time was 50/50. Those results are shown in the following Table 9.

### EXAMPLE 97

As shown in Table 8, a multi-junction thin film silicon solar cell was produced and evaluated in the same manner as Example 51 with the exception of using a composition for a transparent electroconductive film obtained by adding parts by weight of ATO powder having an atomic ratio Sb/(Sb+Sn) of 0.1 and a particle diameter of 0.02 μm as electroconductive fine particles, adding 6.0 parts by weight of ethyl cellulose resin as binder, and adding 0.05 parts by weight of the titanate coupling agent represented by the aforementioned formula (4) as coupling agent followed by adding butyl carbitol acetate as dispersion medium to bring to a total of 100 parts by weight, and coating this composition for a transparent electroconductive film to a film thickness after baking of 190 nm by screen printing. Furthermore, the ratio of fine particles to binder in the transparent electroconductive film at this time was 60/60. Those results are shown in the following Table 9.

### EXAMPLE 98

As shown in Table 8, a multi-junction thin film silicon solar cell was produced and evaluated in the same manner as Example 51 with the exception of using a composition for a transparent electroconductive film obtained by adding 6.0 parts by weight of PTO (P-doped SnO₂) powder having an atomic ratio P/(P+Sn) of 0.1 and a particle diameter of 0.02 μm as electroconductive fine particles, adding 5.0 parts by weight of alkyd resin as binder, and adding 0.05 parts by weight of the titanate coupling agent represented by the aforementioned formula (3) as coupling agent followed by adding ethylene glycol as dispersion medium to bring to a total of 100 parts by weight, and coating this composition for a transparent electroconductive film to a film thickness after baking of 160 nm by offset printing. Furthermore, the ratio of fine particles to binder in the transparent electroconductive film at this time was 60/50. Those results are shown in the following Table 9.

### EXAMPLE 99

As shown in Table 8, a multi-junction thin film silicon solar cell was produced and evaluated in the same manner as Example 51 with the exception of using a composition for a transparent electroconductive film obtained by adding 1.0 part by weight of ATO ponder having an atomic ratio Sb/(Sb+Sn) of 0.1 and a particle diameter of 0.02 μm as electroconductive fine particles, adding 0.2 parts by weight of siloxane polymer as binder, and adding 0.02 parts by weight of the titanate coupling agent represented by the aforementioned formula (3) as coupling agent followed by adding ethanol as dispersion medium to bring to a total of 100 parts by weight, and coating this composition for a transparent electroconductive film to a film thickness after baking of 80 nm by die coating. Furthermore, the ratio of fine particles to binder in the transparent electroconductive film at this time was 10/2. Those results are shown in the following Table 9.

### Comparative Example 6

A multi-junction thin film silicon solar cell was produced and evaluated in the same manner as Example 51 with the exception of depositing ZnO supplemented with about 1×10²¹ cm⁻³ of gallium to a thickness of 80 nm under conditions of a substrate temperature of 150° C. using magnetron sputtering instead of coating the composition for a transparent electroconductive film of Example 51 onto the amorphous silicon layer 13. Those results are shown in the following Table 10.

### Comparative Example 7

A multi-junction thin film silicon solar cell was produced and evaluated in the same manner as Example 51 with the exception of depositing ZnO supplemented with about 1×10²¹ cm⁻³ of gallium to a thickness of 250 nm under conditions of a substrate temperature of 150° C. using magnetron sputtering in the same manner as Comparative Example 6 instead of coating the composition for a transparent electroconductive film of Example 51 onto the amorphous silicon layer 13, followed by immersing this deposited substrate for 15 seconds in 0.5% by weight aqueous HCl solution held at liquid temperature of 15° C. and etching. Those results are shown in the following Table 10.

### Comparative Example 8

A multi-junction thin film silicon solar cell was produced in the same manner as Comparative Example 6 and evaluated in the same manner as Example 51 with the exception of depositing ZnO supplemented with about 1×10^{<}cm⁻³ of aluminum to a thickness of 50 nm under conditions of a substrate temperature of 150° C. using magnetron sputtering instead of the ZnO supplemented with gallium of Comparative Example 6. Those results are shown in the following Table 10.

### Comparative Example 9

A multi-junction thin film silicon solar cell was produced in the same manner as Comparative Example 7 and evaluated in the same manner as Example 51 with the exception of depositing ZnO supplemented with about 1×10²¹ cm⁻³ of aluminum to a thickness of 250 nm under conditions of a substrate temperature of 150° C. using magnetron sputtering instead of the ZnO supplemented with gallium of Comparative Example 7. Those results are shown in the following Table 10.

### Comparative Example 10

A multi-junction thin film silicon solar cell was produced in the same manner as Comparative Example 8 and evaluated in the same manner as Example 51 with the exception of depositing ZnO supplemented with about 1×10²¹ cm⁻³ of aluminum to a thickness of 30 nm. Those results are shown in the following Table 10.

Furthermore, although a silicon solar cell that uses silicon for the power generating layer was used in the aforementioned examples, the present invention is not limited to a silicon solar cell provided it is a multi-junction solar cell, but rather can also be applied to other types of solar cells such as CIG, CIGSS or CIS solar cells, CdTe or Cd solar cells, or organic thin film solar cells.

TABLE 6

| | | | | | | | | | | | Film | Fine |
|---|---|---|---|---|---|---|---|---|---|---|---|---|
| | Composition for Transparent Electroconductive Film | | | | | | | | | | Thickness | Particle/Binder |
| | Fine Particles | | | Binder | | Coupling Agent | | Dispersion Medium | | | After | Ratio |
| | | Particle | Parts | | Parts | | Parts | | Parts | Coating | Baking | After |
| | Type | Diameter | by wt | Type | by wt | Type | by wt | Type | by wt | Method | (nm) | Baking |
| Ex. 51 | ITO | 0.03 | 1.0 | Siloxane | 0.2 | Ti-based | 0.01 | Ethanol | 98.79 | Spin | 80 | 10/2 |
| | (Sn/ | | | polymer | | (3) | | | | coating | | |
| | (Sn + In) = | | | | | | | | | | | |
| | 0.1 | | | | | | | | | | | |
| Ex. 52 | ATO | 0.03 | 1.0 | Siloxane | 0.2 | Al-based | 0.01 | Ethanol | 98.79 | Spin | 90 | 10/2 |
| | (Sb/ | | | polymer | | (1) | | | | coating | | |
| | (Sb + Sn) = | | | | | | | | | | | |
| | 0.1 | | | | | | | | | | | |
| Ex. 53 | PTO (P/ | 0.02 | 1.0 | Siloxane | 0.2 | Ti-based | 0.01 | Ethanol | 98.79 | Spin | 50 | 10/2 |
| | (P + In) = | | | polymer | | (2) | | | | coating | | |
| | 0.1 | | | | | | | | | | | |
| Ex. 54 | ZnO | 0.03 | 1.0 | Acrylic resin | 0.2 | Vinyl | 0.01 | Ethanol | 98.79 | Spin | 60 | 10/2 |
| | | | | | | triethoxy | | | | coating | | |
| | | | | | | silane | | | | | | |
| Ex. 55 | AZO | 0.03 | 0.8 | Cellulose | 0.2 | Ti-based | 0.01 | Butyl | 98.99 | Spin | 30 | 8/2 |
| | (Al/ | | | resin | | (4) | | carbitol | | coating | | |
| | (Al + Zn) = | | | | | | | acetate | | | | |
| | 0.1 | | | | | | | | | | | |
| Ex. 56 | ITO | 0.02 | 1.2 | Epoxy resin | 0.3 | γ-glycidoxy | 0.02 | Toluene | 98.48 | Spin | 70 | 12/3 |
| | (Sn/ | | | | | propyl | | | | coating | | |
| | (Sn + In) = | | | | | trimethoxy | | | | | | |
| | 0.05 | | | | | silane | | | | | | |
| Ex. 57 | ATO | 0.02 | 1.0 | Polyester | 0.5 | Ti-based | 0.03 | Xylene | 98.47 | Spin | 50 | 10/5 |
| | (Sb/ | | | resin | | (5) | | | | coating | | |
| | (Sb + Sn) = | | | | | | | | | | | |
| | 0.05 | | | | | | | | | | | |
| Ex. 58 | PTO (P/ | 0.03 | 1.2 | Acrylurethane | 0.8 | γ-glycidoxy | 0.01 | Isophorone | 98.58 | Spin | 60 | 12/8 |
| | (P + In) = | | | resin | | propyl | | | | coating | | |
| | 0.05 | | | | | trimethoxy | | | | | | |
| | | | | | | silane | | | | | | |
| Ex. 59 | MgO | 0.03 | 0.8 | Polystyrene | 0.6 | Ti-based | 0.02 | Cyclohexanone | 98.58 | Spin | 70 | 8/6 |
| | | | | resin | | (4) | | | | coating | | |
| Ex. 60 | TiO₂ | 0.02 | 1.0 | Polyvinyl | 0.5 | Ti-based | 0.03 | Toluene | 98.47 | Spin | 70 | 10/5 |
| | | | | acetate resin | | (6) | | | | coating | | |
| Ex. 61 | Ag | 0.03 | 0.8 | Polyvinyl | 0.8 | Ti-based | 0.01 | Ethanol | 98.39 | Spin | 50 | 8/8 |
| | | | | alcohol resin | | (7) | | | | coating | | |
| Ex. 62 | Ag—Pd | 0.02 | 0.5 | Siloxane | 0.7 | Ti-based | 0.02 | Ethanol | 98.78 | Spin | 50 | 5/7 |
| | (Ag/Pd = | | | polymer | | (7) | | | | coating | | |
| | 9/1) | | | | | | | | | | | |
| Ex. 63 | Au | 0.03 | 1.0 | Polyamide | 0.8 | Ti-based | 0.01 | Xylene | 98.19 | Spin | 80 | 10/8 |
| | | | | resin | | (8) | | | | coating | | |
| Ex. 64 | Ru | 0.03 | 0.8 | Vinyl | 1.0 | Ti-based | 0.02 | Xylene | 98.18 | Spin | 80 | 8/10 |
| | | | | chloride | | (8) | | | | coating | | |
| | | | | resin | | | | | | | | |
| Ex. 65 | Rh | 0.03 | 1.2 | Acrylate | 1.0 | Ti-based | 0.02 | Ethanol | 97.78 | Spin | 70 | 12/10 |
| | | | | resin | | (8) | | | | coating | | |
| Ex. 66 | ITO | 0.03 | 1.0 | Polycarbonate | 0.2 | Ti-based | 0.01 | Toluene | 98.79 | Spin | 80 | 10/2 |
| | (Sn/ | | | resin | | (3) | | | | coating | | |
| | (Sn + In) = | | | | | | | | | | | |
| | 0.1 | | | | | | | | | | | |
| Ex. 67 | PTO (P/ | 0.02 | 1.0 | Alkyd resin | 0.2 | Ti-based | 0.01 | Cyclohexanone | 98.79 | Spin | 90 | 10/2 |
| | (P + In) = | | | | | (3) | | | | coating | | |
| | 0.1 | | | | | | | | | | | |

TABLE 7

| | | | | | | | | | | | | Fine |
|---|---|---|---|---|---|---|---|---|---|---|---|---|
| | | | | | | | | | | | Film | Particle/ |
| | Composition for Transparent Electroconductive Film | | | | | | | | | | Thickness | Binder |
| | Fine Particles | | | Binder | | Coupling Agent | | Dispersion Medium | | | After | Ratio |
| | | Particle | Parts | | Parts | | Parts | | Parts | Coating | Baking | After |
| | Type | Diameter | by wt | Type | by wt | Type | by wt | Type | by wt | Method | (nm) | Baking |
| Ex. 68 | ATO (Sb/ | 0.03 | 1.0 | Polyurethane | 0.2 | Ti-based | 0.01 | Xylene | 98.79 | Spin | 70 | 10/2 |
| | (Sb + Sn) = | | | resin | | (2) | | | | coating | | |
| | 0.1 | | | | | | | | | | | |
| Ex. 69 | ITO (Sn/ | 0.02 | 1.0 | Polyacetal | 0.2 | Ti-based | 0.01 | Hexane | 98.79 | Spin | 80 | 10/2 |
| | (Sn + In) = | | | resin | | (2) | | | | coating | | |
| | 0.05 | | | | | | | | | | | |
| Ex. 70 | ATO (Sb/ | 0.03 | 1.0 | Ethyl | 0.2 | Ti-based | 0.01 | Hexane | 98.79 | Spin | 80 | 10/2 |
| | (Sb + Sn) = | | | cellulose | | (2) | | | | coating | | |
| | 0.05 | | | resin | | | | | | | | |
| Ex. 71 | PTO (P/ | 0.02 | 1.0 | Al methoxy- | 0.2 | Ti-based | 0.01 | Methanol | 98.79 | Spin | 70 | 10/2 |
| | (P + In) = | | | hydrolysate | | (2) | | | | coating | | |
| | 0.05 | | | | | | | | | | | |
| Ex. 72 | ATO (Sb/ | 0.02 | 1.0 | Alkyl resin/ | 0.2 | Ti-based | 0.01 | Isophorone | 98.79 | Spin | 70 | 10/2 |
| | (Sb + Sn) = | | | polyamide | | (4) | | | | coating | | |
| | 0.1 | | | resin = 7/3 | | | | | | | | |
| Ex. 73 | Si | 0.02 | 1.0 | Siloxane | 0.2 | γ- | 0.01 | Ethanol | 98.79 | Spin | 80 | 10/2 |
| | | | | polymer | | propyl | | | | coating | | |
| | | | | | | trimethoxy | | | | | | |
| | | | | | | silane | | | | | | |
| Ex. 74 | Ga | 0.03 | 1.0 | Alkyd resin | 0.2 | Ti-based | 0.01 | Cyclohexanone | 98.79 | Spin | 80 | 10/2 |
| | | | | | | (2) | | | | coating | | |
| Ex. 75 | Co | 0.02 | 1.0 | Ethyl | 0.2 | Ti-based | 0.01 | Hexane | 98.79 | Spin | 70 | 10/2 |
| | | | | cellulose | | (2) | | | | coating | | |
| | | | | resin | | | | | | | | |
| Ex. 76 | Ca | 0.02 | 1.0 | Polycarbonate | 0.2 | Ti-based | 0.01 | Toluene | 98.79 | Spin | 70 | 10/2 |
| | | | | resin | | (3) | | | | coating | | |
| Ex. 77 | Sr | 0.03 | 1.0 | Polyacetal | 0.2 | Ti-based | 0.01 | Hexane | 98.79 | Spin | 80 | 10/2 |
| | | | | resin | | (3) | | | | coating | | |
| Ex. 78 | Ba(OH)₂ | 0.02 | 1.0 | Polyurethane | 0.2 | Ti-based | 0.01 | Xylene | 98.79 | Spin | 80 | 10/2 |
| | | | | resin | | (4) | | | | coating | | |
| Ex. 79 | Cc | 0.03 | 1.0 | Polyamide | 0.2 | Ti-based | 0.01 | Xylene | 98.79 | Spin | 70 | 10/2 |
| | | | | resin | | (4) | | | | coating | | |
| Ex. 80 | Y | 0.03 | 1.0 | Siloxane | 0.2 | Ti-based | 0.01 | Ethanol | 98.79 | Spin | 70 | 10/2 |
| | | | | polymer | | (5) | | | | coating | | |
| Ex. 81 | Zr | 0.02 | 1.0 | Alkyd resin | 0.2 | Ti-based | 0.01 | Cyclohexanone | 98.79 | Spin | 80 | 10/2 |
| | | | | | | (5) | | | | coating | | |
| Ex. 82 | Sn(OH)₂ | 0.02 | 1.0 | Ethyl | 0.2 | Ti-based | 0.01 | Hexane | 98.79 | Spin | 80 | 10/2 |
| | | | | cellulose | | (6) | | | | coating | | |
| | | | | resin | | | | | | | | |
| Ex. 83 | MgO/ZnO₂ = | 0.03 | 1.0 | Polycarbonate | 0.2 | Ti-based | 0.01 | Toluene | 98.79 | Spin | 80 | 10/2 |
| | 5/5 | | | resin | | (6) | | | | coating | | |
| Ex. 84 | C | 0.03 | 1.0 | Polyacetal | 0.2 | Ti-based | 0.01 | Hexane | 98.79 | Spin | 80 | 10/2 |
| | | | | resin | | (7) | | | | coating | | |

TABLE 8

| | | | | | | | | | | | | Fine |
|---|---|---|---|---|---|---|---|---|---|---|---|---|
| | | | | | | | | | | | Film | Particle/ |
| | Composition for Transparent Electroconductive Film | | | | | | | | | | Thickness | Binder |
| | Fine Particles | | | Binder | | Coupling Agent | | Dispersion Medium | | | After | Ratio |
| | | Particle | Parts | | Parts | | Parts | | Parts | Coating | Baking | After |
| | Type | Diameter | by wt | Type | by wt | Type | by wt | Type | by wt | Method | (nm) | Baking |
| Ex. 85 | SiO₂ | 0.01 | 1.0 | Polyurethane | 0.2 | Ti-based (7) | 0.01 | Xylene | 98.79 | Spin | 80 | 10/2 |
| | | | | resin | | | | | | coating | | |
| Ex. 86 | Cu | 0.03 | 1.0 | Polyamide | 0.2 | Ti-based (8) | 0.01 | Xylene | 98.79 | Spin | 80 | 10/2 |
| | | | | resin | | | | | | coating | | |
| Ex. 87 | Ni | 0.03 | 1.0 | Siloxane | 0.2 | Ti-based (8) | 0.01 | Ethanol | 98.79 | Spin | 80 | 10/2 |
| | | | | polymer | | | | | | coating | | |
| Ex. 88 | Pt | 0.02 | 1.0 | Alkyd resin | 0.2 | Al-based (1) | 0.01 | Cyclohexanone | 98.79 | Spin | 80 | 10/2 |
| | | | | | | | | | | coating | | |
| Ex. 89 | Ir | 0.03 | 1.0 | Ethyl | 0.2 | Al-based (1) | 0.01 | Hexane | 98.79 | Spin | 70 | 10/2 |
| | | | | cellulose | | | | | | coating | | |
| | | | | resin | | | | | | | | |
| Ex. 90 | PTO (P/ | 0.02 | 1.4 | Polycarbonate | 0.6 | Al-based | 0.04 | Toluene | 97.96 | Spin | 110 | 14/6 |
| | (P + In) = | | | resin | | (1)/Ti-based | | | | coating | | |
| | 0.1 | | | | | (3) = 5/5 | | | | | | |
| Ex. 91 | ITO | 0.02 | 1.2 | Siloxane | 0.3 | Ti-based (3) | 0.02 | Ethanol | 98.48 | Spray | 100 | 12/3 |
| | (Sn/ | | | polymer | | | | | | coating | | |
| | (Sn + In) = | | | | | | | | | | | |
| | 0.1 | | | | | | | | | | | |
| Ex. 92 | PTO (P/ | 0.03 | 1.2 | Siloxane | 0.03 | Ti-based (3) | 0.02 | Ethanol | 98.48 | Dispenser | 100 | 12/3 |
| | (P + In) = | | | polymer | | | | | | coating | | |
| | 0.1 | | | | | | | | | | | |
| Ex. 93 | ATO | 0.02 | 1.0 | Siloxane | 0.3 | Ti-based (3) | 0.01 | Ethanol | 98.69 | Knife | 80 | 10/3 |
| | (Sb/ | | | polymer | | | | | | coating | | |
| | (Sb + sn) = | | | | | | | | | | | |
| | 0.1 | | | | | | | | | | | |
| Ex. 94 | ITO | 0.02 | 1.0 | Siloxane | 0.3 | Ti-based (2) | 0.01 | Ethanol | 98.69 | Slit | 80 | 10/3 |
| | (Sn/ | | | polymer | | | | | | coating | | |
| | (Sn + In) = | | | | | | | | | | | |
| | 0.05 | | | | | | | | | | | |
| Ex. 95 | ATO | 0.03 | 1.0 | Siloxane | 0.3 | Ti-based (2) | 0.01 | Ethanol | 98.69 | Inkjet | 80 | 10/3 |
| | (Sb/ | | | polymer | | | | | | coating | | |
| | (Sb + Sn) = | | | | | | | | | | | |
| | 0.05 | | | | | | | | | | | |
| Ex. 96 | PTO (P/ | 0.02 | 5.0 | Acrylic reain | 5.0 | Ti-based (2) | 0.05 | Ethylene | 89.95 | Gravure | 120 | 50/50 |
| | (P + In) = | | | | | | | glycol | | printing | | |
| | 0.05 | | | | | | | | | | | |
| Ex. 97 | ATO | 0.02 | 6.0 | Ethyl | 6.0 | Ti-based (4) | 0.05 | Butyl | 87.95 | Screen | 190 | 60/60 |
| | (Sb/ | | | cellulose | | | | carbitol | | printing | | |
| | (Sb + Sn) = | | | resin | | | | acetate | | | | |
| | 0.1 | | | | | | | | | | | |
| Ex. 98 | PTO (P/ | 0.02 | 6.0 | Alkyd resin | 5.0 | Ti-based (3) | 0.05 | Ethylene | 88.95 | Offset | 160 | 60/50 |
| | (P + In) = | | | | | | | glycol | | printing | | |
| | 0.1 | | | | | | | | | | | |
| Ex. 99 | ATO | 0.02 | 1.0 | Siloxane | 0.2 | Ti-based (3) | 0.02 | Ethanol | 98.78 | Die | 80 | 10/2 |
| | (Sb/ | | | polymer | | | | | | coating | | |
| | (Sb + Sn) = | | | | | | | | | | | |
| | 0.1 | | | | | | | | | | | |

TABLE 9

| | | Short-circuit | |
|---|---|---|---|
| | | Current | Conversion |
| | | Density | efficiency |
| | Refractive | (relative | (relative |
| | Index (—) | value) | value) |
| Ex. 51 | 1.7 | 1.00 | 1.00 |
| Ex. 52 | 1.5 | 1.12 | 1.15 |
| Ex. 53 | 1.6 | 1.21 | 1.32 |
| Ex. 54 | 1.6 | 1.03 | 1.10 |
| Ex. 55 | 1.7 | 1.95 | 0.98 |
| Ex. 56 | 1.7 | 0.96 | 0.97 |
| Ex. 57 | 1.8 | 1.22 | 1.25 |
| Ex. 58 | 1.6 | 1.03 | 1.08 |
| Ex. 59 | 1.7 | 0.99 | 1.01 |
| Ex. 60 | 1.6 | 1.02 | 1.04 |
| Ex. 61 | 1.5 | 1.03 | 1.05 |
| Ex. 62 | 1.6 | 1.31 | 1.24 |
| Ex. 63 | 1.6 | 1.28 | 1.35 |
| Ex. 64 | 1.7 | 1.14 | 1.20 |
| Ex. 65 | 1.5 | 1.09 | 1.13 |
| Ex. 66 | 1.5 | 1.10 | 1.11 |
| Ex. 67 | 1.6 | 1.08 | 1.06 |
| Ex. 68 | 1.5 | 1.19 | 1.21 |
| Ex. 69 | 1.7 | 0.99 | 0.97 |
| Ex. 70 | 1.5 | 1.08 | 1.06 |
| Ex. 71 | 1.6 | 1.14 | 1.15 |
| Ex. 72 | 1.6 | 1.18 | 1.15 |
| Ex. 73 | 1.5 | 1.04 | 1.09 |
| Ex. 74 | 1.7 | 1.05 | 1.06 |
| Ex. 75 | 1.5 | 1.01 | 1.04 |
| Ex. 76 | 1.6 | 1.20 | 1.18 |
| Ex. 77 | 1.7 | 1.15 | 1.14 |
| Ex. 78 | 1.6 | 0.98 | 0.99 |
| Ex. 79 | 1.5 | 1.12 | 1.09 |
| Ex. 80 | 1.6 | 1.09 | 1.06 |
| Ex. 81 | 1.5 | 1.12 | 1.09 |
| Ex. 82 | 1.6 | 0.97 | 1.04 |
| Ex. 83 | 1.7 | 1.02 | 1.00 |
| Ex. 84 | 1.6 | 1.04 | 1.07 |
| Ex. 85 | 1.6 | 1.04 | 1.02 |
| Ex. 86 | 1.7 | 1.04 | 0.99 |
| Ex. 87 | 1.6 | 1.01 | 0.98 |
| Ex. 88 | 1.7 | 0.99 | 1.02 |
| Ex. 89 | 1.9 | 0.98 | 0.97 |
| Ex. 90 | 1.5 | 1.19 | 1.17 |
| Ex. 91 | 1.7 | 1.22 | 1.20 |
| Ex. 92 | 1.6 | 1.07 | 1.08 |
| Ex. 93 | 1.5 | 1.26 | 1.25 |
| Ex. 94 | 1.6 | 1.17 | 1.19 |
| Ex. 95 | 1.7 | 1.08 | 1.09 |
| Ex. 96 | 1.5 | 1.24 | 1.21 |
| Ex. 97 | 1.5 | 1.18 | 1.22 |
| Ex. 98 | 1.6 | 1.07 | 1.09 |
| Ex. 99 | 1.5 | 1.25 | 1.21 |

TABLE 10

| | Electro- | Refrac- | Short-circuit | |
|---|---|---|---|---|
| | conductive | tive | current | Conversion |
| | film | index | density | efficiency |
| | composition | (—) | (relative value) | (relative value) |
| Comp. Ex. 6 | ZnO + Ga | 2.1 | 0.85 | 0.87 |
| Comp. Ex. 7 | ZnO + Ga | 2.2 | 0.80 | 0.88 |
| Comp. Ex. 8 | ZnO + Al | 2.0 | 0.90 | 0.94 |
| Comp. Ex. 9 | ZnO + Al | 2.1 | 0.83 | 0.90 |
| Comp. Ex. 10 | ZnO + Al | 2.2 | 0.85 | 0.92 |

As is clear from Tables 9 and 10, Examples 51 to 99 demonstrate low refractive indices as well as high short-circuit current densities and conversion efficiencies, and were confirmed to allow the obtaining of superior cell performance in comparison with the transparent electroconductive films of Comparative Examples 6 to 10 in which ZnO films were formed by sputter deposition.

### INDUSTRIAL APPLICABILITY

According to the present invention, a transparent electroconductive film can be produced by a wet coating method using a coating material that satisfies each of the requirements of favorable phototransmittance, high electrical conductivity, low refractive index and the like required when using in a multi-junction solar cell, while also enabling running costs to be reduced since the transparent electroconductive film is produced without using a vacuum deposition method. In addition, light reflection properties between photoelectric conversion layers are optimized by facilitating adjustment of optical properties such as refractive index of the transparent electroconductive film that are related to a difference in refractive indices between photoelectric conversion layers and the transparent electroconductive film. Moreover, since the transparent electroconductive film of the present invention is composed of two layers consisting of an electroconductive fine particle layer and a binder layer, it demonstrates superior adhesion to an amorphous silicon layer serving as a base in comparison with single transparent electroconductive films, while also offering the advantage of exhibiting little change over time.

### BRIEF DESCRIPTION OF THE REFERENCE SYMBOLS

10 Multi-junction solar cell
11 Transparent substrate
12 Front side electrode layer
13 Amorphous silicon layer
14 Transparent electroconductive film
14a Electroconductive fine particle layer
14b Binder layer
15 Microcrystalline silicon layer
16 Back side electrode layer
24 Transparent electroconductive film
24a Coated film of electroconductive fine particles
24b Coated film of binder dispersion

1-11. (canceled)

12. A method for manufacturing a photoelectric conversion device comprising a first photoelectric conversion layer; a second photoelectric conversion layer; and a transparent electroconductive film provided between the first and second photoelectric conversion layers,
the method comprising:
forming an amorphous silicon layer as the first photoelectric conversion layer,
coating a fine particle dispersion containing electroconductive fine particles and a dispersion medium on the first photoelectric conversion layer using a wet coating method, the fine particle dispersion containing 80 to 99 weight % of the dispersion medium and the electroconductive fine particles having an average particle diameter of 10 to 100 nm,
drying the fine particle dispersion to form a fine particle coated film,
coating a binder dispersion containing a binder and a dispersion medium on the fine particle coated film to form a binder layer impregnating the electroconductive fine particle layer, the binder consisting essentially of one or more of polymers selected from the group consisting of siloxane polymer and metal alkoxide hydrolysate, and one or more of coupling agents selected from the group consisting of a silane coupling agent, an aluminate coupling agent, and a titanate coupling agent, and the binder dispersion containing 5 to 50 weight % of the binder as a solid fraction, and
baking the fine particle layer and the binder layer to form the transparent electroconductive film on the first photoelectric conversion layer,
the electroconductive component is present in the transparent electroconductive film within the range of 5 to 95% by weight, and
the electroconductive film has a thickness of 5 to 200 nm and a refractive index of 1.1 to 2.0.

13. The method for manufacturing a photoelectric conversion device according to claim 12, wherein
the electroconductive fine particles are first fine particles composed of an oxide, hydroxide or composite compound of one or two or more elements selected from the group consisting of Zn, In, Sn, Sb, Si, Al, Ga, Co, Mg, Ca, Sr, Ba, Ce, Ti, Y and Zr, or a mixture of two or more thereof.

14. The method for manufacturing a photoelectric conversion device according to claim 12, wherein
the electroconductive fine particles are second fine particles composed of nanoparticles consisting of a mixed alloy containing one or two or more elements selected from the group consisting of C, Si, Cu, Ni, Ag, Pd, Pt, Au, Ru, Rh and Ir.

15. The method for manufacturing a photoelectric conversion device according to claim 12, wherein
the electroconductive fine particles are a mixture of both the first fine particles and the second fine particles, the first fine particles being composed of an oxide, hydroxide or composite compound of one or two or more elements selected from the group consisting of Zn, In, Sn, Sb, Si, Al, Ga, Co, Mg, Ca, Sr, Ba, Ce, Ti, Y and Zr, or a mixture of two or more thereof, and
the second fine particles being composed of nanoparticles consisting of a mixed alloy containing one or two or more of elements selected from the group consisting of C, Si, Cu, Ni, Ag, Pd, Pt, Au, Ru, Rh and Ir.

16. The method for manufacturing a photoelectric conversion device according to claim 12, wherein the polymer contains methoxyhydrolysate of Al as the metal alkoxide.

17. The method for manufacturing a photoelectric conversion device according to claim 12, wherein
the coupling agent is selected from the group consisting of coupling agents represented by the following formulas (1) to (8), and vinyltriethoxysilane, γ-glycidoxypropyltrimethoxysilane and g-methacryloxypropyltrimethoxysilane.

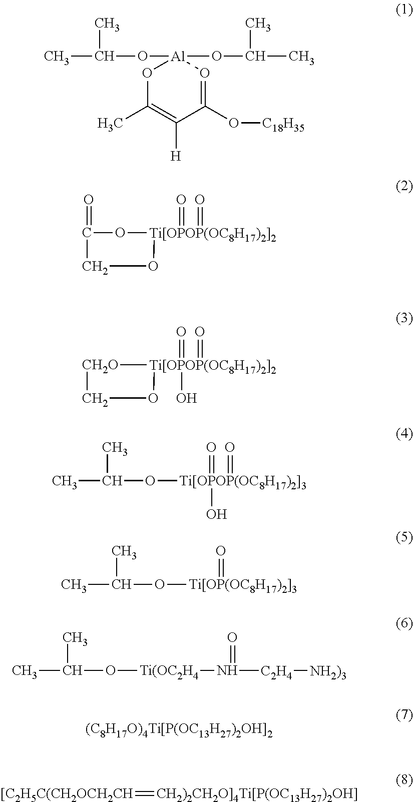

18. The method for manufacturing a photoelectric conversion device according to claim 12, wherein
the electroconductive component is present in the electroconductive film within the range of 30 to 85% by weight, the electroconductive film has a thickness of 20 to 100 nm and a refractive index of 1.3 to 1.8.

19. The method for manufacturing a photoelectric conversion device according to claim 12, wherein
the electroconductive fine particles are one or more selected from the group consisting of indium-doped tin oxide powder, ZnO powder, antimony-doped tin oxide powder, aluminum-doped zinc oxide powder, indium-doped zinc oxide powder, and tantalum-doped zinc oxide powder.

20. The method for manufacturing a photoelectric conversion device according to claim 12, wherein the dispersion medium used in the electroconductive fine particle dispersion and the binder dispersion contains at least one of water, ethanol, isopropanol, butanol, hexanol, acetone, methyl ethyl ketone, methyl isobutyl ketone, cyclohexanone, isophorone, 4-hydroxy-4-methyl-2-pentanone, toluene, xylene, hexane, cyclohexane, N,N-dimethylformamide, N,N-dimethylacetoamide, dimethylsulfoxide, ethylene glycol, and ethyl cellosolve.

21. A method for manufacturing a multi-junction solar cell comprising a transparent substrate; a first electrode layer formed on the transparent substrate; a first photoelectric conversion layer formed on the electrode layer; a transparent electroconductive film formed on the first photoelectric conversion layer; a second photoelectric conversion layer formed on the transparent electroconductive film; and a second electrode layer formed on the second photoelectric conversion layer,
the method comprising forming the first photoelectric conversion layer, the transparent electroconductive film, and second photoelectric conversion layer by the method for manufacturing the photoelectric conversion device according to claim 12.
